(19) United States
(12) Patent Application Publication
(10) Pub. No.: US 2025/0191664 A1
(43) Pub. Date: Jun. 12, 2025

(54) OPERATION METHOD OF MEMORY, MEMORY, AND MEMORY SYSTEM

(71) Applicant: Yangtze Memory Technologies Co., Ltd., Wuhan (CN)

(72) Inventors: Xiangnan ZHAO, Wuhan (CN); Bo LI, Wuhan (CN); Chenhui LI, Wuhan (CN); Hongtao LIU, Wuhan (CN); Shuai ZHANG, Wuhan (CN); Wei QI, Wuhan (CN)

(21) Appl. No.: 18/897,813

(22) Filed: Sep. 26, 2024

(30) Foreign Application Priority Data
Dec. 11, 2023 (CN) 202311705591.8

(51) Int. Cl. G11C 16/34; G11C 16/08; G11C 16/10

(52) U.S. Cl. CPC G11C 16/3459; G11C 16/08; G11C 16/102

(57) ABSTRACT

The present disclosure provides an operation method of a memory, a memory, and a memory system, and relates to the technical field of memory technology. An example method includes: at a first program stage, performing a program operation on memory cells of a target group including a first memory cell and a second memory cell for a first number of times, wherein the first memory cell and the second memory cell have different target program states, then performing a verify operation using a verify voltage for the target group; and after the second memory cell passes the verification that uses the verify voltage for the target group, performing the program operation on the second memory cells for a second number of times, and inhibiting the second memory cell from being verified.

### CROSS-REFERENCE TO RELATED APPLICATIONS

This application claims the benefit of priority to Chinese Application No. 202311705591.8, filed on Dec. 11, 2023, the contents of which are hereby incorporated by reference in their entirety.

### TECHNICAL FIELD

The present disclosure relates to the technical field of memory technology, and particularly to an operation method of a memory, a memory, and a memory system.

### BACKGROUND

A flash memory is a widely used non-volatile memory that can be electrically erased and reprogrammed. The flash memory comprises a NOR flash memory and a NAND flash memory. A threshold voltage of a memory cell in the flash memory may be changed to a desired level to perform read, program, and erase operations. For the NAND flash memory, the erase operation can be performed at a block level, and the program operation or read operation can be performed at a page level.

The information disclosed in the above Background section is merely for enhancement of understanding of the background of the present disclosure, and may comprise information that does not constitute the prior art that is already known to those of ordinary skill in the art.

### SUMMARY

The present disclosure is intended to provide an operation method of a memory, a memory, and a memory system.

Other features and advantages of the present disclosure will become apparent through the following detailed description, or will be learned in part through the practice of the present disclosure.

One aspect of the present disclosure provides an operation method of a memory, comprising: at a first program stage, performing a program operation on memory cells of a target group for a first number of times, wherein the memory cells of the target group comprise a first memory cell and a second memory cell, a target program state of the first memory cell is a first program state, and a target program state of the second memory cell is a second program state; performing a verify operation on the memory cells of the target group using a verify voltage for the target group; and after the second memory cell passes the verification that uses the verify voltage for the target group, performing the program operation on the second memory cell for a second number of times, and inhibiting the second memory cell from being verified.

According to an example of the present disclosure, a threshold voltage of the memory cell in the first program state is less than a threshold voltage of the memory cell in the second program state, the verify voltage for the target group is for verifying whether the memory cell is in a target intermediate state, and the target intermediate state is a program target for the first memory cell at the first program stage.

According to an example of the present disclosure, a threshold voltage of the memory cell in the first program state is less than a threshold voltage of the memory cell in the second program state, the second program state differs from the first program state by a third number of program states, wherein the second number is greater than the third number; or the second number is equal to the third number.

According to an example of the present disclosure, the method further comprises: at the first program stage, after performing the program operation on the second memory cell for the second number of times, inhibiting the second memory cell from being programmed.

According to an example of the present disclosure, the method further comprises: at a second program stage, performing the program operation and the corresponding verify operation on the memory cells of the target group, to program the memory cells of the target group to a corresponding target program state.

According to an example of the present disclosure, the method further comprises: at the first program stage, after the first memory cell passes the verification that uses the verify voltage for the target group, inhibiting the first memory cell from being programmed.

According to an example of the present disclosure, the method further comprises: at the first program stage, for the memory cells in the target group that do not pass the verification that uses the verify voltage for the target group, continuing performing the program operation, and after performing the program operation, continuing performing the verify operation using the verify voltage for the target group.

According to an example of the present disclosure, during performing the program operation on the second memory cell for the second number of times, a program voltage is applied to a selected word line, and an intermediate voltage or a ground voltage is applied to a bit line coupled with the second memory cell, the memory cells coupled with the selected word line comprising the memory cells of the target group, and the intermediate voltage being greater than the ground voltage.

According to an example of the present disclosure, during performing the program operation on the memory cells of the target group for the first number of times, the program voltage is applied to the selected word line, and the intermediate voltage or the ground voltage is applied to the bit line coupled with the second memory cell.

According to an example of the present disclosure, the after the second memory cell passes the verification that uses the verify voltage for the target group, performing the program operation on the second memory cell for a second number of times, and inhibiting the second memory cell from being verified comprises: after the second memory cell passes the verification that uses the verify voltage for the target group, applying a verify inhibit voltage to a bit line coupled with the second memory cell between at least two adjacent program operations during performing the program operation on the second memory cell for the second number of times.

According to an example of the present disclosure, memory cells to be programmed in the memory have m target program states, at the first program stage, the memory cells to be programmed in the memory are divided into n groups according to the target program states of the memory cells, n is an integer greater than or equal to 1, and m is an integer greater than n, and the target group belongs to one of the n groups, the target program states of the memory cells of different groups among the n groups are different, and the memory cells of the same group have the same verify voltage.

According to an example of the present disclosure, the target group is the 1st group, the verify voltages for the 1st group to the nth group increase sequentially, and the first number is greater than 1, and the method further comprises: at the first program stage, performing the verify operation on the memory cells of the 1st group using the verify voltage for the 1st group between at least two adjacent program operations during performing the program operation on the memory cells of the target group for the first number of times.

According to an example of the present disclosure, the target group is the kth group, k is an integer greater than or equal to 1 and less than n, and the verify voltages for the 1st group to the nth group increase sequentially, and the method further comprises: at the first program stage, after performing the verify operation on the memory cells of the target group using the verify voltage for the target group, performing the verify operation on at least part of the memory cells of the (k+1)th group using the verify voltage for the (k+1)th group.

According to an example of the present disclosure, the target group is the kth group, k is an integer greater than 1 and less than or equal to n, the verify voltages for the 1st group to the nth group increase sequentially, and the first number is greater than 1, and the method further comprises: at the first program stage, before performing the verify operation on the memory cells of the target group using the verify voltage for the target group, performing the verify operation on the memory cells of the kth group using the verify voltage for the jth group between at least two adjacent program operations during performing the program operation on the memory cells of the kth group for the first number of times, wherein j is greater than or equal to 1 and less than k.

According to an example of the present disclosure, m is any integer from 7 to 15, and n is any integer from 2 to 5.

According to an example of the present disclosure, the numbers of target program states of the memory cells in different groups among the n groups are the same or different.

According to an example of the present disclosure, the memory cell is a quadruple level cell QLC, and the method further comprises: dividing the memory cells to be programmed, which have 15 target program states, in the memory into 4 groups in order from the minimum to the maximum threshold voltages corresponding to the target program states, wherein the memory cells in the 1st to 3rd group have 4 target program states, the memory cells in the 4th group have 3 target program states, and the target group is any one of the 1st to 4th group.

According to an example of the present disclosure, the memory cells in the target group have i target program states, and i is an integer greater than 1, the first program state is the target program state corresponding to the minimum threshold voltage among the i target program states, and the second program state is any one of the i target program states other than the target program state corresponding to the minimum threshold voltage.

Yet another aspect of the present disclosure provides a memory, comprising: a memory cell array comprising memory cells of a target group; a plurality of word lines coupled to rows of the memory cell array respectively; a plurality of bit lines coupled to memory strings of the memory cell array respectively; and a peripheral circuit coupled to the memory cell array through the word lines and the bit lines, and configured to: at a first program stage, perform a program operation on the memory cells of the target group for a first number of times, wherein the memory cells of the target group comprise a first memory cell and a second memory cell, a target program state of the first memory cell is a first program state, and a target program state of the second memory cell is a second program state; perform a verify operation on the memory cells of the target group using a verify voltage for the target group; and after the second memory cell passes the verification that uses the verify voltage for the target group, perform the program operation on the second memory cell for a second number of times, and inhibit the second memory cell from being verified.

According to an example of the present disclosure, the peripheral circuit comprises: a plurality of page buffer circuits coupled to the plurality of bit lines respectively, wherein each page buffer circuit comprises: a data latch circuit comprising: a first data latch circuit configured to latch group identification information of the target group to which a memory cell belongs; and a second data latch circuit configured to latch to-be-programmed state identification information of the memory cell in the target group to which it belongs, wherein the group identification information and the to-be-programmed state identification information indicate the target program state of the memory cell; and a state latch circuit configured to latch first result information of performing the verify operation on the memory cells of the target group using the verify voltage for the target group, and the peripheral circuit is further configured to: if the memory cell is determined as the second memory cell according to the group identification information and the to-be-programmed state identification information, and it is determined, according to a result of performing the verify operation, that the second memory cell passes the verification that uses the verify voltage for the target group, perform the program operation on the second memory cell for a second number of times.

According to an example of the present disclosure, each page buffer circuit further comprises: a sensing latch circuit configured to latch data based on a current flowing through the bit line; and a low-voltage latch circuit configured to latch second result information of performing the verify operation.

According to an example of the present disclosure, a threshold voltage of the memory cell in the first program state is less than a threshold voltage of the memory cell in the second program state, the verify voltage for the target group is for verifying whether the memory cell is in a target intermediate state, the target intermediate state is a program target for the first memory cell at the first program stage, and the second program state differs from the first program state by a third number of program states, wherein the second number is greater than or equal to the third number; and the peripheral circuit is further configured to: at the first program stage, after performing the program operation one time during performing the program operation on the second memory cell for the second number of times, update the to-be-programmed state identification information in the second data latch circuit corresponding to the second memory cell, and perform the program operation on the second memory cell next time according to the updated to-be-programmed state identification information, or inhibit the second memory cell from being programmed.

According to an example of the present disclosure, the first data latch circuit and the second data latch circuit employ different or same data latch circuits.

According to an example of the present disclosure, the peripheral circuit is further configured to: at a second program stage, perform the program operation and the corresponding verify operation on the memory cells of the target group, to program the memory cells of the target group to a corresponding target program state.

Yet another aspect of the present disclosure provides an operation method of a memory, comprising: at a first program stage, performing a program operation on target memory cells coupled with a selected word line, wherein the target memory cells comprise memory cells of a target group, wherein: within a first time period, applying a program voltage to the selected word line for a first number of times, and applying a verify voltage for the target group to the selected word line; and within a second time period after the first time period, applying a program voltage to the selected word line for a second number of times, and applying a verify voltage for the target group to the selected word line.

According to an example of the present disclosure, the memory cells of the target group comprise a first memory cell and a second memory cell, a target program state of the first memory cell is a first program state, and a target program state of the second memory cell is a second program state. The method further comprises: within the second time period, applying a verify inhibit voltage to a bit line coupled with the second memory cell between at least two applications of the program voltage during applying the program voltage to the selected word line for the second number of times, wherein the second memory cell passes the verification that uses the verify voltage for the target group.

According to an example of the present disclosure, the target memory cells have m target program states, the target memory cells are divided into n groups, m is a positive integer greater than n, and n is a positive integer greater than or equal to 1, the target program states of the memory cells of different groups among the n groups are different, the memory cells of the same group have the same verify voltage, and the verify voltages for the target groups from the 1st group to the nth group increase sequentially, and when the target group is the 1st group among the n groups, the verify voltage for the 1st group is equal to the verify voltage for verifying whether the memory cells are in the target program state corresponding to the minimum threshold voltage among the m target program states.

According to an example of the present disclosure, the memory cell is a QLC, and the target memory cells, which have 15 target program states, are divided into 4 groups in order from the minimum to the maximum threshold voltages corresponding to the target program states, wherein the memory cells in the 1st to 3rd group have 4 target program states, the memory cells in the 4th group have 3 target program states, and the target group is any one of the 1st to 4th group, and the first program state is the target program state corresponding to the minimum threshold voltage among the 4 target program states of the memory cells of the target group, the verify voltage for the target group is for verifying whether the memory cell is in a target intermediate state, and the target intermediate state is a program target for the first memory cell at the first program stage.

According to an example of the present disclosure, within the second time period, when applying the program voltage to the selected word line for the second number of times, an intermediate voltage or a ground voltage is applied to the bit line coupled with the second memory cell that passes the verification that uses the verify voltage for the target group, and the intermediate voltage is greater than the ground voltage.

According to an example of the present disclosure, the method further comprises: at a second program stage, performing the program operation and the corresponding verify operation on the target memory cells coupled with the selected word line, to program the target memory cells to a corresponding target program state.

Yet another aspect of the present disclosure provides an operation method of a memory, wherein memory cells in the memory are divided into at least one target group according to different target program states, the memory cells in the at least one target group correspond to at least two target program states, the at least two target program states comprise a first program state. The method comprises: at a first program stage, performing a verify operation on the memory cells in the same target group using a same verify voltage, wherein after the memory cells in the same target group, which correspond to remaining program states other than the first program state, pass the verify operation that uses the verify voltage for the corresponding target group, the programming is inhibited after an additional program operation is applied for a predetermined number of times, and the verification is inhibited after the additional program operation.

Yet another aspect of the present disclosure provides a memory system, comprising the memory described in any one of the above and a controller coupled with the memory. The memory is configured to perform the operation method of the memory described in any one of the above.

Yet another aspect of the present disclosure provides a computer-readable storage medium. The computer-readable storage medium stores a computer-executable instruction. Any one of the above-mentioned methods is implemented when the executable instruction is performed by a processor.

It should be understood that, the above general description and the following detailed description are merely examples, and cannot limit the present disclosure.

### BRIEF DESCRIPTION OF THE DRAWINGS

The above-mentioned and other objects, features, and advantages of the present disclosure will become more apparent by describing examples thereof in detail with reference to the drawings.

FIG. 1 shows a block diagram of an example system having a memory in examples of the present disclosure.

FIG. 2A shows a block diagram of a memory system.

FIG. 2B shows a block diagram of another memory system.

FIG. 3 is a schematic circuit diagram of a memory comprising a peripheral circuit provided by examples of the present disclosure.

FIG. 4 is a schematic diagram of a peripheral circuit provided by examples of the present disclosure.

FIG. 5 is a flow diagram of an operation method of a memory shown according to an example.

FIG. 6 is a flow diagram of another operation method of a memory shown according to an example.

FIG. 7 is a flow diagram of yet another operation method of a memory according to the operation methods shown in FIGS. 5 and 6.

FIG. 8 shows a schematic waveform diagram of word line voltages of a QLC NAND flash memory at a first program stage in some examples.

FIG. 9 is a schematic waveform diagram of word line voltages of a QLC NAND flash memory at a first program stage shown by examples of the present disclosure.

FIG. 10A is a flow diagram of still another operation method of a memory shown according to an example.

FIG. 10B shows a voltage waveform diagram of applying an operation method of a memory of examples of the present disclosure according to FIG. 10A.

FIG. 11 shows a schematic diagram of distribution of threshold voltages of second memory cells after a second number of program operations.

FIG. 12 shows another schematic diagram of distribution of threshold voltages of second memory cells after a second number of program operations.

FIG. 13 shows a schematic diagram of distribution of threshold voltages of memory cells obtained after a program operation is performed on a QLC NAND memory by employing a method provided by examples of the present disclosure.

FIG. 14 shows a trend diagram of indexes obtained after a test operation is performed on a QLC NAND memory by employing a method provided by examples of the present disclosure.

FIG. 15 is another schematic waveform diagram of word line voltages of a QLC NAND flash memory at a first program stage shown by examples of the present disclosure.

FIG. 16 shows a schematic diagram of each program state of QLC memory cells indicated by group identification information and information of a state to be programmed.

FIG. 17 shows a method for updating to-be-programmed state identification information during a process of applying several program pulse voltages according to FIG. 16.

FIG. 18 shows a block diagram of a page buffer/sense amplifier.

FIG. 19 shows another schematic diagram of each program state of QLC memory cells indicated by group identification information and information of a state to be programmed.

FIG. 20 shows yet another schematic diagram of each program state of QLC memory cells indicated by group identification information and information of a state to be programmed.

### DETAILED DESCRIPTION

Examples are described more comprehensively with reference to the drawings. However, examples can be implemented in various forms and should not be construed as limited to the examples set forth herein. In contrast, these examples are provided for more thorough and complete understanding of the present disclosure, and to fully convey the concept of the examples to a person skilled in the art. The drawings are merely schematic illustrations of the present disclosure and are not necessarily drawn to scale. The same reference numbers in the drawings denote same or similar parts, and thus detailed descriptions will be omitted.

Furthermore, the described features, structures or characteristics may be combined in one or more examples in any proper manner. In the following description, many specific details are provided thereby giving a full understanding of the examples of the present disclosure. However, those skilled in the art will realize that the technical solutions of the present disclosure may be practiced and one or more of the particular details described may be omitted, or other methods, devices, operations, etc., may be employed. In other cases, well-known structures, methods, devices, examples, or operations are not shown or described in detail to avoid overshadowing and obscuring aspects of the present disclosure.

Furthermore, the terms “first”, “second” and the like are used for descriptive purposes only and are not to be construed as indicating or implying relative importance or implicitly specifying the number of technical features indicated. Thus, features defined by “first” and “second” may explicitly or implicitly include one or more of such features. In the description of the present disclosure, “a plurality of” means at least two, for example, two, three, or the like, unless otherwise explicitly specified. The symbol “/” indicates that the related objects are in an “or” relationship.

In the present disclosure, unless otherwise clearly specified and limited, the terms “connect” and the like should be interpreted broadly. For example, the term “connect” may be interpreted as being electrically connected or being able to communicate with each other; and the term “connect” may be interpreted as being directly connected, or indirectly connected by means of a medium. For those of ordinary skill in the art, specific meanings of the foregoing terms in the present disclosure may be understood based on specific situations.

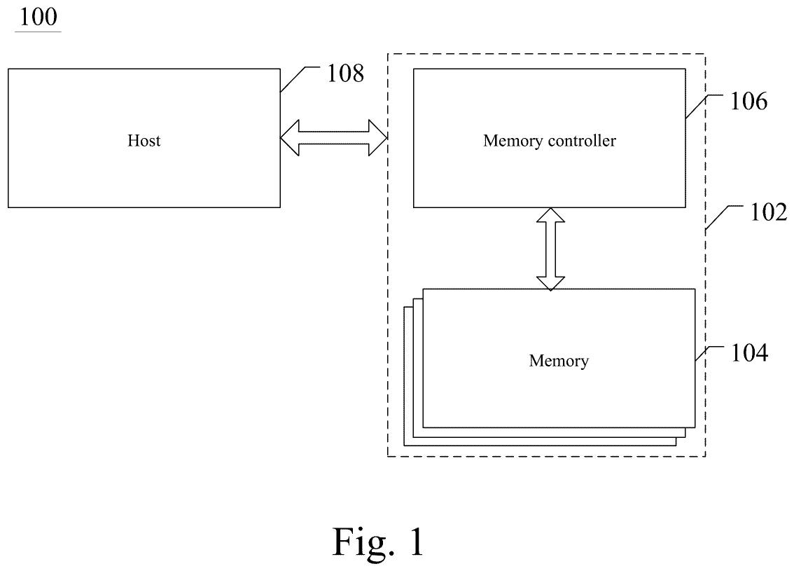

FIG. 1 shows a block diagram of an example system having a memory in examples of the present disclosure. The system 100 may comprise a mobile phone, a desktop computer, a laptop computer, a tablet computer, a vehicle computer, a gaming console, a printer, a positioning apparatus, a wearable electronic apparatus, a smart sensor, a virtual reality apparatus, an augmented reality apparatus, or any other suitable electronic apparatus having a memory.

As shown in FIG. 1, the system 100 may comprise a host 108 and a memory system 102, and the memory system 102 is provided with one or more memories 104 and a memory controller 106. The host 108 may be a processor (for example, a Central Processing Unit (CPU)) of an electronic apparatus or a System-on-Chip (SoC) (e.g. an application processor). The host 108 may be configured to send or receive data to or from the memory 104.

The memory 104 may be any memory in the present disclosure, for example, a non-volatile memory. The non-volatile memory may be a NAND flash memory (e.g. a three-dimensional (3D) NAND flash memory).

In some examples, the memory controller 106 is coupled to the memory 104 and the host 108, and is configured to control the memory 104. The memory controller 106 may manage data stored in the memory 104, and communicate with the host 108.

In some examples, the memory controller 106 is configured to send a command to the memory 104 to cause the memory 104 to perform an operation method of a memory provided by examples of the present disclosure.

In some examples, the memory controller 106 is designed for operating in a low duty-cycle environment, such as secure digital (SD) cards, Compact Flash (CF) Cards, Universal Serial Bus (USB) flash drives, or other media for use in electronic apparatuses, such as personal computers, digital cameras, mobile phones, etc.

In some examples, the memory controller 106 is designed for operating in a high duty-cycle environment, for example, Solid-State Disks (SSDs) or embedded Multi-Media Cards (eMMCs) which may be used as data memories for mobile apparatuses, such as smartphones, tablets, laptop computers, etc., and enterprise memory arrays. The memory controller 106 may be configured to send a command to the memory 104 to cause the memory 104 to perform operations, such as read, erase, and program operations.

The memory controller 106 may further be configured to manage various functions with respect to data stored or to be stored in the memory 104, including, but not limited to, bad-block management, garbage collection, logical-to-physical address conversion, wear leveling, etc.

In some examples, the memory controller 106 is further configured to process error correction codes (ECCs) with respect to the data read from or written to the memory 104. The memory controller 106 may further execute any other suitable functions, for example, format the memory 104. The memory controller 106 may communicate with an external apparatus (e.g., the host 108) according to a specific communication protocol. For example, the memory controller 106 may communicate with the external apparatus through at least one of various interface protocols, such as a USB protocol, an MMC protocol, a Peripheral Component Interconnection (PCI) protocol, a PCI-Express (PCI-E) protocol, an Advanced Technology Attachment (ATA) protocol, a Serial-ATA protocol, a Parallel-ATA protocol, a Small Computer Small Interface (SCSI) protocol, an Enhanced Small Disk Interface (ESDI) protocol, an Integrated Drive Electronics (IDE) protocol, a Firewire protocol, etc.

The memory controller 106 and the one or more memories 104 may be integrated into various types of storage apparatuses, for example, be comprised in the same package (such as a universal flash storage (UFS) package or an eMMC package). That is to say, the memory system 102 may be implemented and packaged into different types of end electronic products.

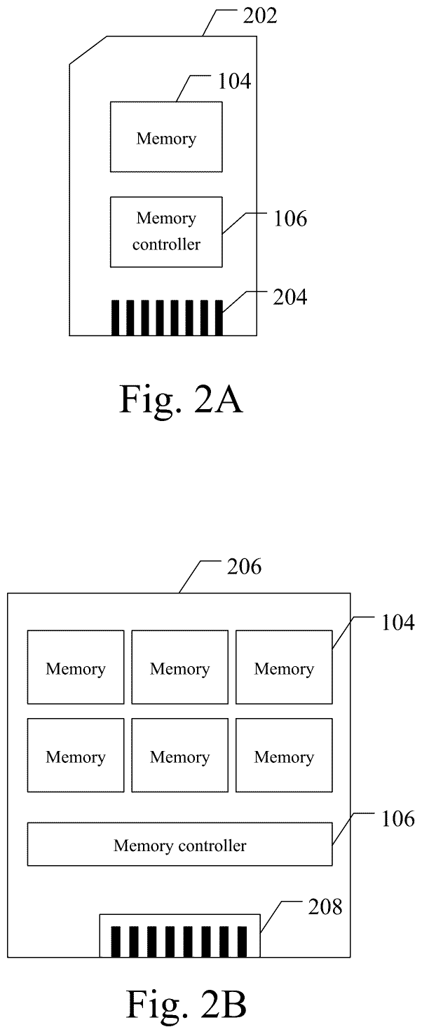

FIG. 2A shows a block diagram of a memory system. As shown in FIG. 2A, the memory controller 106 and the single memory 104 may be integrated into a memory card 202. The memory card 202 may comprise a personal computer memory card international association (PCMCIA) Card (PC), a CF card, a smart media (SM) card, a memory stick, a multimedia card (such as an MMC, an RS-MMC, an MMC micro card, etc.), an SD card (such as an SD card, a mini SD card, a micro SD card, an SDHC card, etc.), a UFS card, etc. The memory card 202 may further comprise a memory card connector 204 coupling the memory card 202 with a host (e.g., the host 108 in FIG. 1).

FIG. 2B shows a block diagram of another memory system. As shown in FIG. 2B, the memory controller 106 and the plurality of memories 104 may be integrated into the SSD 206. The SSD 206 may further comprise an SSD connector 208 coupling the SSD 206 with the host (e.g., the host 108 in FIG. 1). In some examples, at least one of a storage capacity or an operation speed of the SSD 206 is greater than that of the memory card 202.

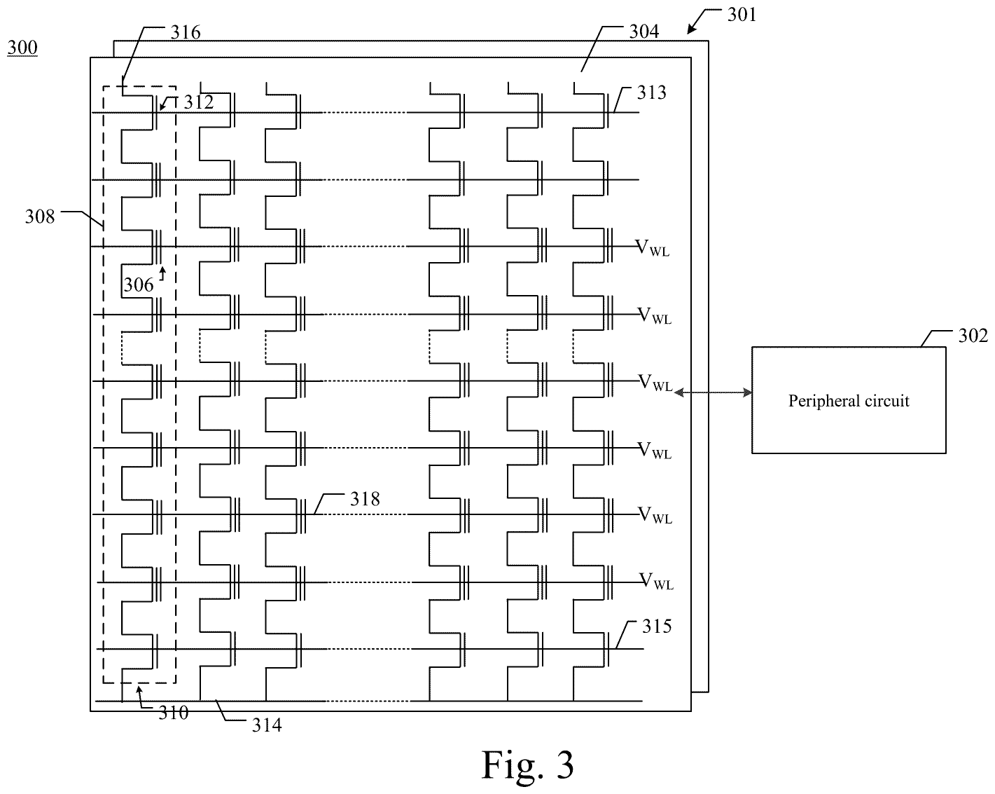

FIG. 3 is a schematic circuit diagram of a memory 300 comprising a peripheral circuit provided by examples of the present disclosure. The memory 300 may be an example of the memory 104 in FIG. 1. The memory 300 may comprise a memory cell array 301 and a peripheral circuit 302 coupled to the memory cell array 301. The memory cell array 301 may be a NAND flash memory cell array, wherein memory cells 306 are provided in the form of an array of NAND flash memory strings 308, and each memory string 308 extends vertically above a substrate (not shown).

In some examples, the peripheral circuit 302 is configured to perform an operation method provided by examples of the present disclosure. It can be understood that, the peripheral circuit 302 may be configured to perform the operation method provided by the examples of the present disclosure according to a received instruction of the memory controller 106.

In some examples, each memory string 308 comprises the plurality of memory cells 306 coupled in series and stacked vertically. Each memory cell 306 may hold a continuous analog value, such as voltage or charge, which depends on the number of electrons trapped within a region of the memory cells 306. Each memory cell 306 may be either a floating gate type memory cell that comprises a floating gate transistor, or a charge trapping type memory cell that comprises a charge trapping transistor.

In some examples, each memory cell 306 may store 1 bit of data, 2 bits of data, or more bits of data, i.e., may be in a Single-Level Cell (SLC) type, a Multi-Level Cell (MLC) type, a Triple-Level Cell (TLC) type, a Quad-Level Cell (QLC) type, or a more advanced type. p (p being a positive integer)-level cell may have 2^{P} states (for example, one state corresponds to one threshold voltage distribution interval), such that p bits of data may be stored. The SLC-type memory cell may have 2 states, and thus may store 1 bit of data; the MLC-type memory cell may have 4 states, and thus may store 2 bits of data; the TLC-type memory cell may have 8 states, and thus may store 3 bits of data; the QLC-type memory cell may have 16 states, and thus may store 4 bits of data, and so on. The 2^{p} states may comprise one erase state and 2^{p}-1 program states. The p-level cell type NAND flash memory may be in units of pages, and perform at least one of a program or read operation on data page by page. During the program operation, the p-level cell type NAND flash memory cell is programmed to have 2^{p} states, and when one memory cell is programmed to a target state among the 2^{p} states, the memory cell is said to be in a target program state. As shown in FIG. 3, each memory string 308 may comprise a Source Select Gate (SSG) 310 at its source end and a Drain Select Gate (DSG) 312 at its drain end. The SSG 310 and the DSG 312 may be configured to activate a selected memory string 308 during read and program operations.

In some examples, sources of the memory strings 308 in a same block 304 are coupled through a same Source Line (SL) 314 (e.g. a common SL). For example, all the memory strings 308 in the same block 304 have an Array Common Source (ACS). As shown in FIG. 3, the memory strings 308 may be organized into a plurality of blocks 304, and each of the plurality of blocks 304 may have a common source line 314 (e.g., coupled to the ground). In some examples, each block 304 is a basic data unit for an erase operation, i.e., all of the memory cells 306 on the same block 304 are erased at the same time.

In some examples, the DSG 312 of each memory string 308 is coupled to a respective Bit Line (BL) 316, and data may be read or written from the bit line 316 via an output bus (not shown). Each memory string 308 may be configured to be selected or unselected by at least one of applying a select voltage (e.g., above a threshold voltage of a transistor having the DSG 312) or an unselect voltage (e.g., 0 V) to the respective TSG 312 via one or more DSG lines 313 or applying a select voltage (e.g., above a threshold voltage of a transistor having the SSG 310) or an unselect voltage (e.g., 0 V) to the respective SSG 310 via one or more SSG lines 315.

As shown in FIG. 3, the memory cells 306 of the memory string 308 may be coupled through word lines (WL) 318 that select which row of memory cells 306 is affected by the read and program operations. The peripheral circuit 302 may be coupled to the memory cell array 301 through the bit lines 316, the word lines 318, the source lines 314, the SSG lines 315, and the DSG lines 313. The peripheral circuit 302 may comprise any suitable analog, digital, and hybrid signal circuits for facilitating operations of the memory cell array 301 by applying and sensing at least one of voltage signals or current signals to and from each target memory cell 306 via the bit lines 316, the word lines 318, the source lines 314, the SSG lines 315, and the DSG lines 313. The peripheral circuit 302 may comprise various types of peripheral circuits formed using the Metal-Oxide-Semiconductor (MOS) technology.

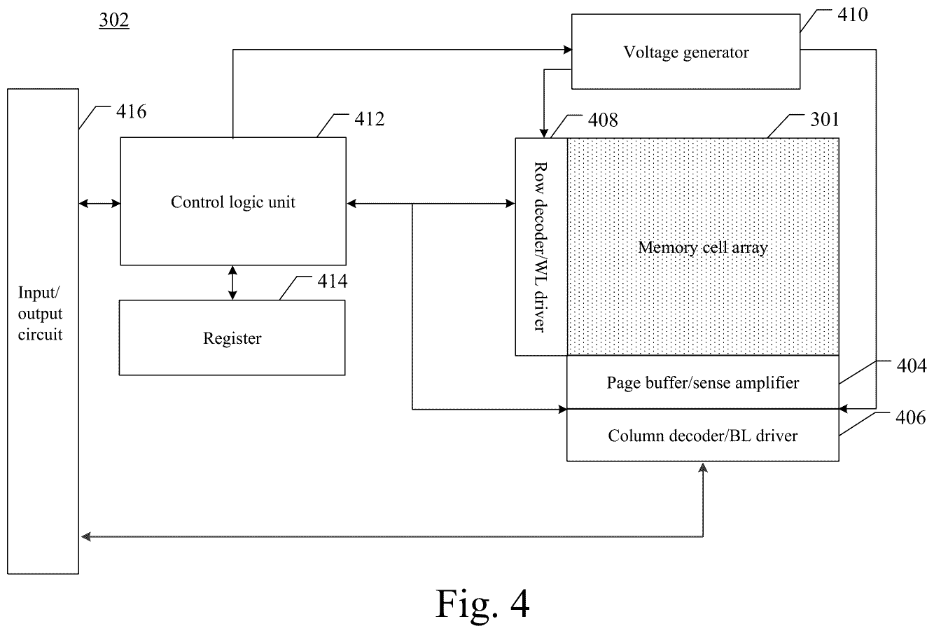

FIG. 4 is a schematic diagram of a peripheral circuit provided by examples of the present disclosure. As shown in FIG. 4, the peripheral circuit 302 may comprise a page buffer/sense amplifier 404, a column decoder/BL driver 406, a row decoder/WL driver 408, a voltage generator 410, a control logic unit 412, a register 414, an input/output (I/O) circuit 416, and a data bus 418. It is to be understood that, in some examples, additional peripheral circuits not shown in FIG. 4 may also be comprised as well.

In some examples, the page buffer/sense amplifier 404 may be configured to read and program (write) data from and to the memory cell array 301 according to a control signal from the control logic unit 412. For example, the page buffer/sense amplifier 404 may store one page of program data (write data) to be programmed into the memory cell array 301. For another example, the page buffer/sense amplifier 404 may also sense a low power signal from the bit line 316 that represents a data bit stored in the memory cell 306, and amplify a small voltage swing to a recognizable logic level in the read operation. The column decoder/BL driver 406 may be configured to be controlled by the control logic unit 412, and select one or more memory strings 308 by applying a bit line voltage generated from the voltage generator 410.

The row decoder/WL driver 408 may be configured to be controlled by the control logic unit 412, select/unselect the blocks 304 of the memory cell array 301, and select/unselect the word lines 318 of the blocks 304. The row decoder/WL driver 408 may further be configured to drive the word line 318 by using the word line voltage generated from the voltage generator 410. In some examples, the row decoder/WL driver 408 may further select/unselect and drive the SSG line 314 and the DSG line 313. The voltage generator 410 may be configured to be controlled by the control logic unit 412, and generate the word line voltage (such as, a read voltage, a program voltage, a pass voltage, a local voltage, a verify voltage, etc.), the bit line voltage, a source line voltage, etc., which are to be supplied to the memory cell array 301.

The control logic unit 412 may be coupled to each portion of the peripheral circuit 302 and configured to control operations of each portion. The register 414 may be coupled to the control logic unit 412, and may comprise a state register, a command register, and an address register, so as to store state information, a command operation code (OP code), and a command address for controlling the operations of each peripheral circuit. The input/output circuit 416 may be coupled to the control logic unit 412, and act as a control buffer to buffer and relay a control command received from a host (not shown in FIG. 4) to the control logic unit 412, and to buffer and relay the state information received from the control logic unit 412 to the host. The input/output circuit 416 may also be coupled to the column decoder/bit line driver 406 via the data bus 418 and act as a data I/O interface and a data buffer to buffer and relay the data to and from the memory cell array 301.

During the program operation of the p-level cell type memory, program operations of a plurality of stages may be performed to increase read margins, for example, the plurality of stages may comprise a first program stage of programming the memory cells to threshold voltage intervals of which distribution is relatively wide (e.g. which may be a coarse program stage), and a second program stage of programming the memory cells to threshold voltage intervals of which distribution is relatively narrow (e.g. which may be a fine program stage). Using a QLC NAND flash memory as an example, in some examples, a 16-16 two-stage program solution is employed. First, the memory cells are programmed to 16 threshold voltage intervals of which distributions are relatively wide at the coarse program stage, and then the memory cells are programmed to 16 threshold voltage intervals of which distributions are relatively narrow at the fine program stage. When the memory cells are programmed to 16 threshold voltage intervals of which distributions are relatively wide at the coarse program stage, verification needs to be performed after a program pulse is applied each time, so as to ensure that the memory cells are programmed to the corresponding ones among the 16 threshold voltage intervals of which distributions are relatively wide. In this case, the verification occupies nearly half the time of the coarse program stage, thus significantly increasing program time, and limiting the performance of the memory.

Therefore, the present disclosure provides an operation method of a memory. By dividing the memory cells into at least one target group according to different target program states, the memory cells in one target group correspond to at least two target program states. The memory cells of the same target group are programmed at the first program stage, and then a same verify voltage is utilized for verification. An additional program operation is applied, for a predetermined number (i.e. a second number) of times, to the memory cells (i.e. second memory cells) that pass the verification and correspond to the remaining program states other than the first program state, without performing the verification (i.e. inhibiting the verification), such that the total number of verifications performed in the first program stage is reduced, thereby shortening the program time of the memory, and improving the performance of the memory.

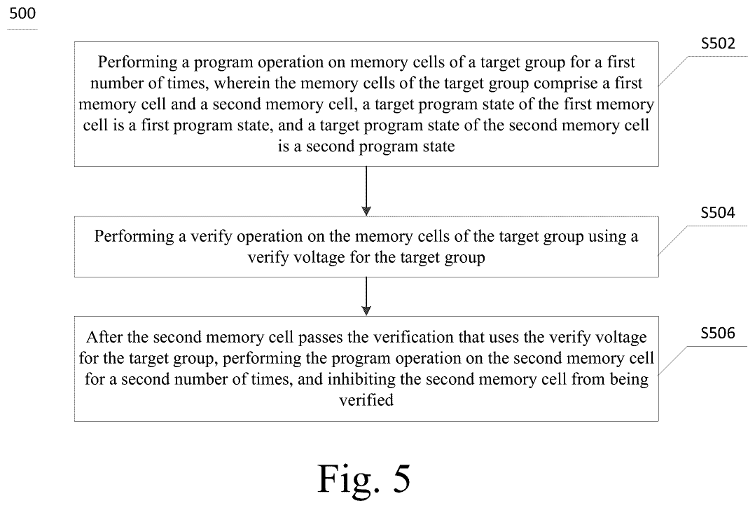

FIG. 5 is a flow diagram of an operation method of a memory shown according to an example. The method shown in FIG. 5, for example, may be applied to the memory cell array shown in FIG. 3. An instruction may be sent to the peripheral circuit shown in FIG. 3 by the memory controller shown in FIG. 1, FIG. 2A, or FIG. 2B, so as to perform the method shown in FIG. 5.

Referring to FIG. 5, the method 500 provided by the examples of the present disclosure may comprise operation S502 to operation S506 performed at the first program stage.

In operation S502, performing a program operation on memory cells of a target group for a first number of times, wherein the memory cells of the target group comprise a first memory cell and a second memory cell, a target program state of the first memory cell is a first program state, and a target program state of the second memory cell is a second program state.

In some examples, the first program stage may be the coarse program stage, and the second program stage may be the fine program stage. The first program state may be the target program state of the first memory cells at the second program stage, and the second program state may be the target program state of the second memory cells at the second program stage.

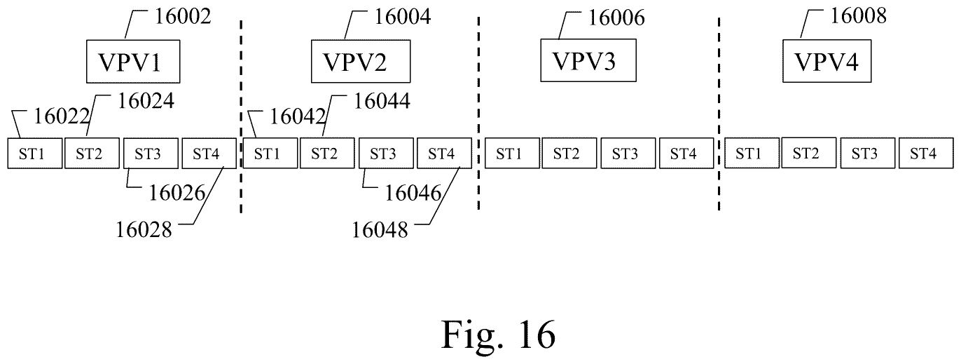

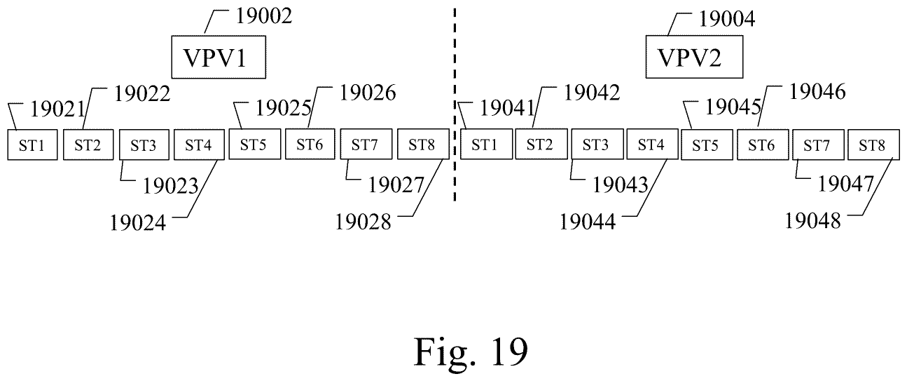

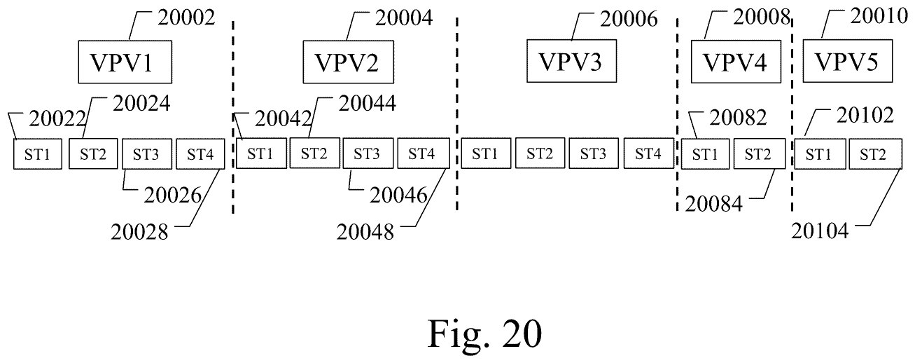

In some examples, the memory cells to be programmed in the memory may have m target program states. At the first program stage, the memory cells to be programmed in the memory are divided into n groups according to the target program states of the memory cells, n is an integer greater than or equal to 1, and m is an integer greater than n, and the target group belongs to one of the n groups, the target program states of the memory cells of different groups among the n groups are different. m may be any one of the integers from 7 to 15, and n may be any one of the integers from 2 to 5. The numbers of target program states of the memory cells in different groups among the n groups are the same or different. Examples may be referred to FIG. 16, FIG. 19, and FIG. 20. For example, when m is 7, the memory cell is the TLC-type memory cell; and when m is 15, the memory cell is the QLC-type memory cell.

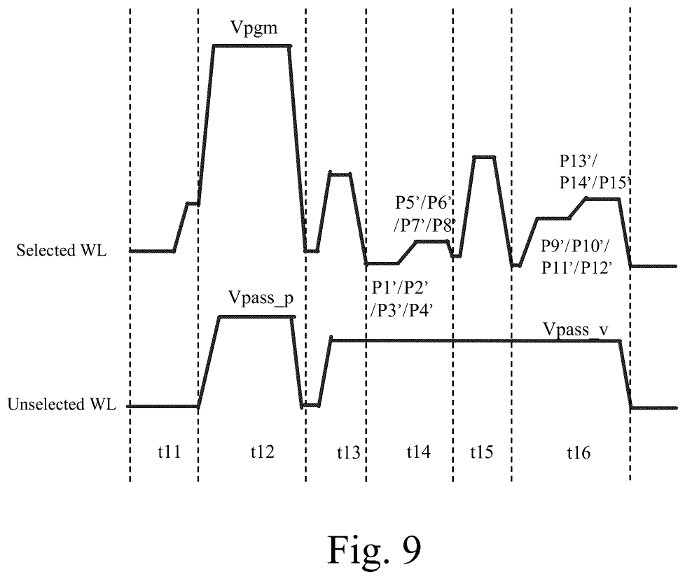

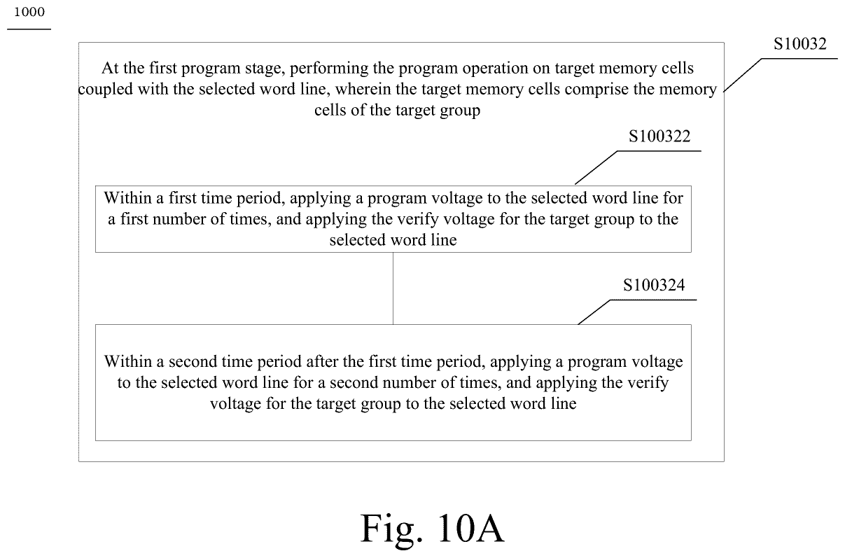

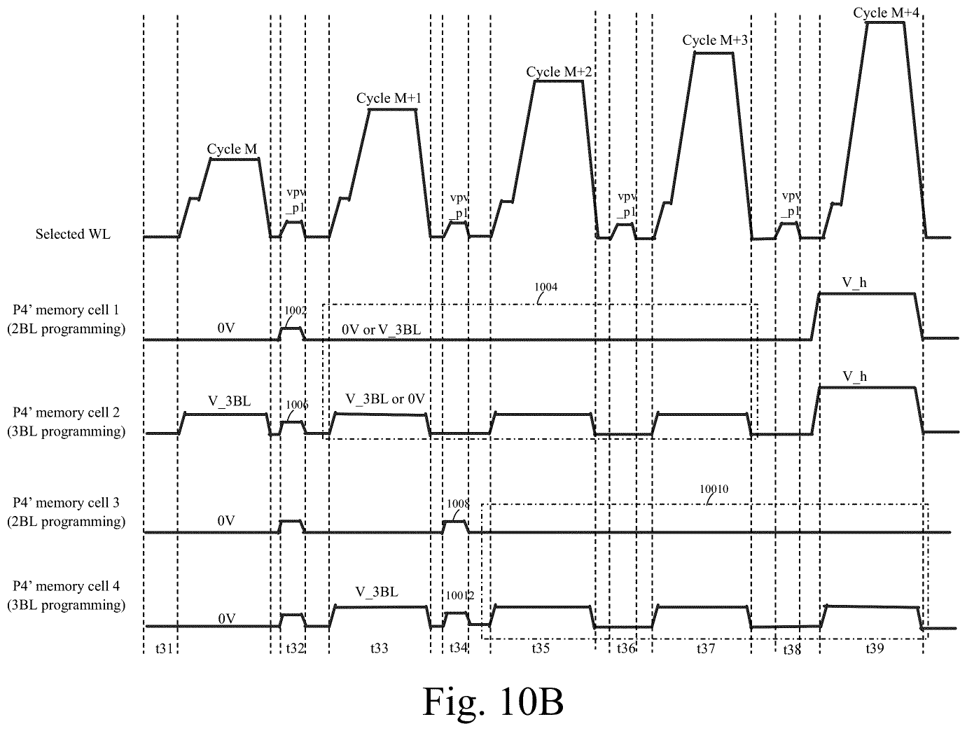

When verify voltages for the 1st group to the nth group increase sequentially, if the target group is the 1st group, i.e., the target group corresponds to the minimum verify voltage in the n groups, the verify operation may be performed on the memory cells of the 1st group using the verify voltage for the 1st group between at least two adjacent program operations during performing the program operation on the memory cells of the target group for the first number (an integer greater than 1) of times. For example, the verify operation may be performed using the verify voltage for the 1st group between every two program operations, and a particular example may be referred to FIG. 10B. For another example, the verify operation may be performed using the verify voltage for the 1st group between every two program operations, and the verify operation may be performed on the memory cells of the 2nd group using the verify voltage for the 2nd group; and a particular example may be referred to FIG. 9.

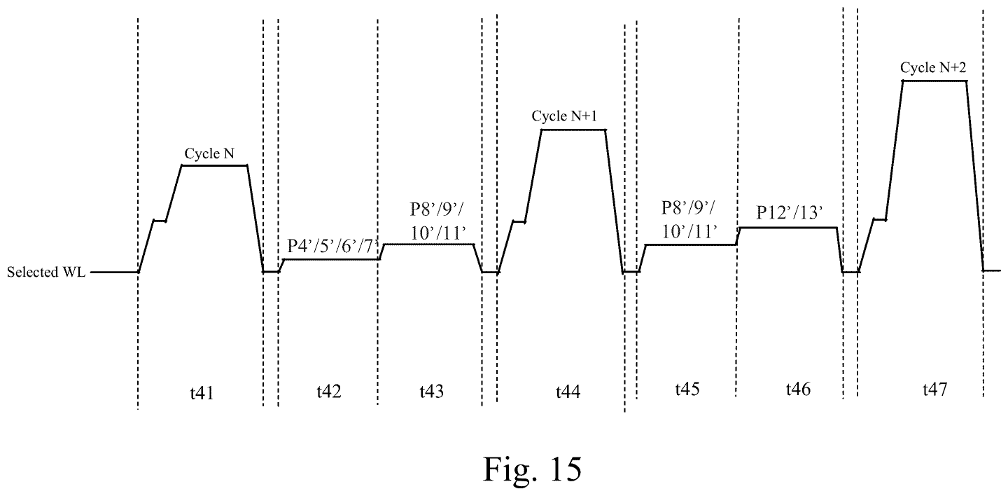

If the target group is the kth group, and k is an integer greater than 1 and less than or equal to n, during a verify time period between the at least two adjacent program operations during performing the program operation on the memory cells of the kth group for the first number (the integer greater than 1) of times, and before the verify operation performed on the memory cells of the kth group using the verify voltage for the kth group, the verify operation may be performed on the memory cells of the kth group using the verify voltage for the jth group, and j is an integer greater than or equal to 1 and less than k. A waveform in FIG. 15 may show an example of this case. For example, when the verify voltage of the 2nd group is employed for verification at a time period t42, the memory cells of the 2nd group and the memory cells of the 3rd group may be verified at the same time. If there are memory cells of the 3rd group that do not pass the verification that uses the verify voltage for the 2nd group, the memory cells may not be verified using the verify voltage for the 3rd group at the time period t42, and after a program pulse of a cycle N+1 is applied at a time period t44, the memory cells may be verified using the verify voltage for the 3rd group at a time period t45.

In some examples, the first number may be set according to actual situations, and the first number is greater than 1. For example, different target groups correspond to different first numbers, and the target groups corresponding to larger verify voltages may correspond to higher first numbers.

In some examples, during the first number of the program operations performed on the memory cells of the target group, a program voltage may be applied to a selected word line (the memory cells coupled with the selected word line comprising the memory cells of the target group), and an intermediate voltage or a ground voltage (e.g. 0 V) may be applied to a bit line coupled with the memory cells of the target group. The intermediate voltage (e.g. 3BL voltage) is greater than the ground voltage. For example, an Incremental Step Pulse Programming (ISPP) scheme may be employed, i.e., program voltages gradually increasing are applied to the selected word line for a first number of times, and each program operation is followed by at least one verify operation. Particular examples may be referred to FIGS. 10B and 15.

In operation S504, performing a verify operation on the memory cells of the target group using a verify voltage for the target group.

For example, the memory cells to be programmed in the memory are divided into n groups according to the target program states of the memory cells, in the examples of the present disclosure, at the first program stage, the memory cells of the same group among the n groups have the same verify voltage, and the memory cells of different groups have different verify voltages.

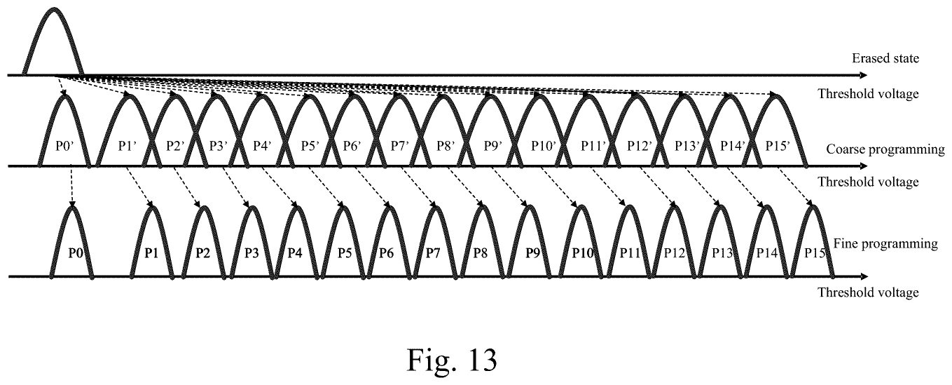

In some examples, a threshold voltage of the memory cell in the first program state is less than a threshold voltage of the memory cell in the second program state, the verify voltage for the target group is for verifying whether the memory cell is in a target intermediate state, and the target intermediate state is a program target for the first memory cell at the first program stage. For example, each program state of the second program stage may correspond to one intermediate state at the first program stage. For example, a state corresponding to the first program state at the first program stage may be a first intermediate state (i.e., the above-mentioned target intermediate state), a state corresponding to the second program state at the first program stage may be a second intermediate state, i.e., the number of program states by which the second program state and the first program state differ is the same as the number of intermediate states by which the second intermediate state and the first intermediate state differ. A correspondence relationship between the intermediate states of the first program stage and the program states of the second program stage may be referred to FIG. 13. That is, after the program operation is performed on the first memory cells and the second memory cells, a smaller value between a threshold voltage corresponding to the program target for the first memory cell at the first program stage and a threshold voltage corresponding to the program target for the second memory cell at the first program stage is selected as the verify voltage value for verification.

In some examples, for example, the memory cells to be programmed in the memory are divided into n groups according to the target program states of the memory cells, and the target group is the kth group, after the verify operation is performed on the memory cells of the kth group using the verify voltage for the kth group, and before the next program operation, the verify operation may also be performed on at least part of the memory cells of the (k+1)th group using the verify voltage for the (k+1)th group, i.e., the verify voltages for two adjacent target groups may be used for verification between two adjacent program operations. An example of this case is shown in FIG. 15.

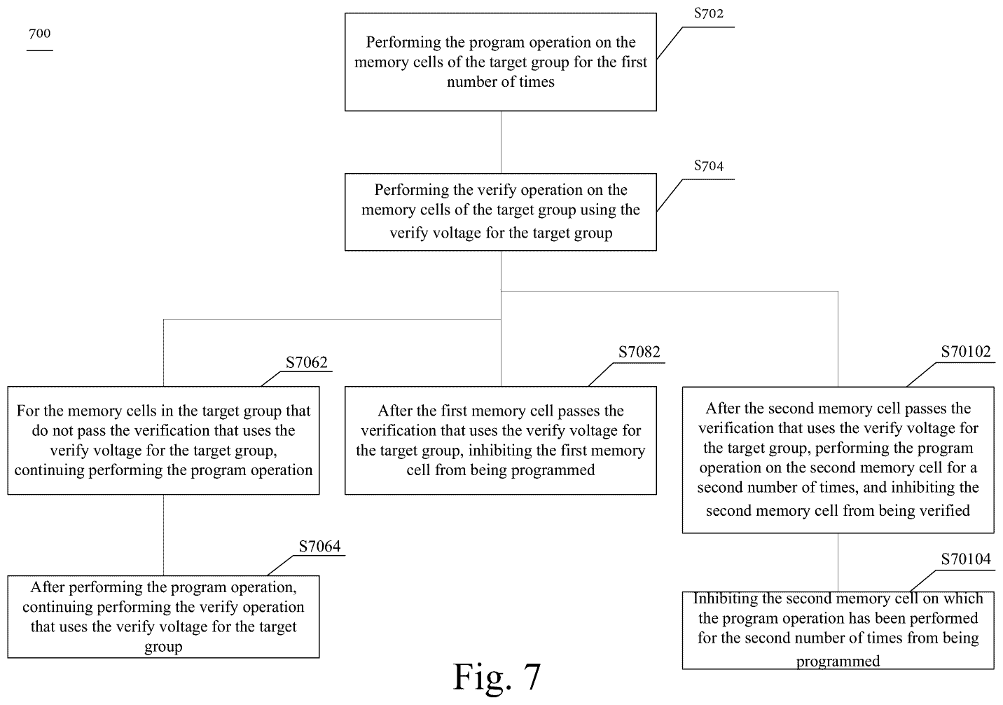

In some examples, after the verify operation is performed on the memory cells of the target group using the verify voltage for the target group, there may be part of the memory cells that do not pass the verification, after the memory cells not passing the verification are continuously programmed, the verify operation may be performed by continuously using the verify voltage for the target group, until the memory cells pass the verification, and subsequent operations performed on the second memory cells and first memory cells that pass the verification are distinguished. A particular example may be referred to FIG. 7.

In operation S506, after the second memory cell passes the verification that uses the verify voltage for the target group, performing the program operation on the second memory cell for a second number of times, and inhibiting the second memory cell from being verified.

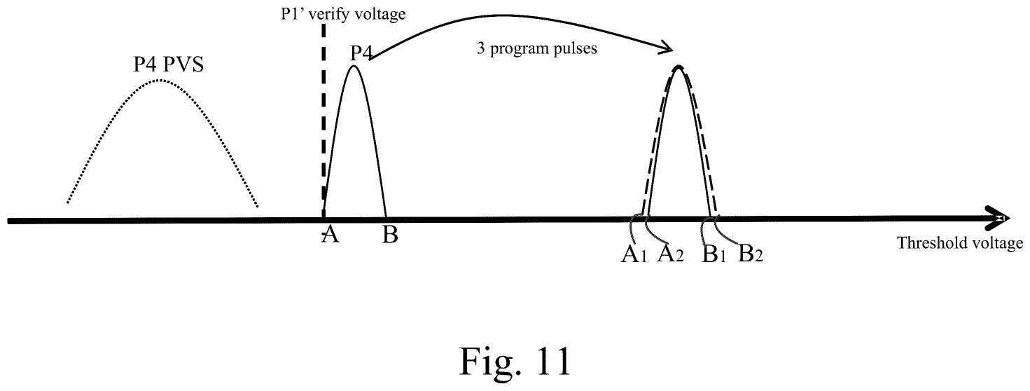

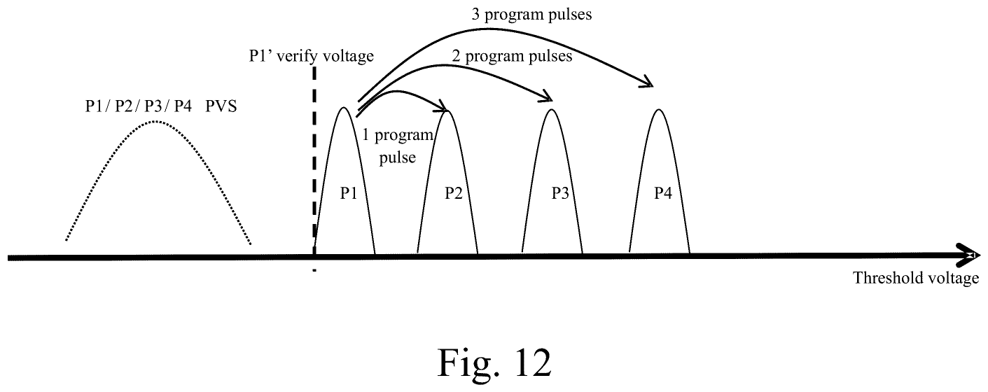

For example, a smaller value between a threshold voltage corresponding to the program target for the first memory cell at the first program stage and a threshold voltage corresponding to the program target for the second memory cell at the first program stage (i.e. the above-mentioned first intermediate state and the second intermediate state) is selected as the verify voltage value for verification (the threshold voltages corresponding to the first program state of the first memory cells in the examples of the present disclosure are smaller), if the second program state and the first program state differ by a second number of program states, i.e. the number of program states by which the second program state and the first program state differ is the same as the number of times of the program operation performed on the second memory cells that pass the verification that uses the verify voltage for the target group, and at a verify stage after each of the one or more program operations (at this stage, other memory cells to be verified may be verified, such as the memory cells that do not pass the verification that uses the verify voltage for the group to which the memory cells belong), these second memory cells are inhibited from being verified. That is, the number of program states by which the second program state and the first program state differ is the same as the number of program pulses “touch-typed” to the second memory cells that pass the verification that uses the verify voltage for the target group, so as to program these second memory cells to a desired target state at the first program stage. FIGS. 11 and 12 show threshold voltage distribution of the memory cells after “touch-typing”.

If the second program state and the first program state differ by a third number (less than a second number) of the program states, the second number of the program operations is performed on the second memory cells that pass the verification that uses the verify voltage for the target group without verification, i.e., the second number (exceeds the third number) of the program pulses are “touch-typed” to the second memory cells that pass the verification that uses the verify voltage for the target group. This case is suitable for the memory cells that are difficult to program, and a degree that the second number exceeds the third number may be set according to particular situations of the memory cells.

In some examples, during the second number of the program operations performed on the second memory cells, a program voltage may be applied to a selected word line (the memory cells coupled with the selected word line comprising the memory cells of the target group), and an intermediate voltage or a ground voltage may be applied to a bit line coupled with the second memory cells. Particular examples may be referred to FIGS. 10A and 10B.

In some examples, after the second memory cell passes the verification that uses the verify voltage for the target group, a verify inhibit voltage may be applied to a bit line coupled with the second memory cell between at least two adjacent program operations during performing the program operation on the second memory cell for the second number of times to inhibit the second memory cell from being verified, wherein the verify inhibit voltage may be 0 V, or may also be other volts that are less than a voltage on the corresponding bit line during a normal verify operation. FIG. 10B shows an example that the verify inhibit voltage is 0 V.

According to the operation method of the memory provided by the examples of the present disclosure, the number of verifications performed on the second memory cells is reduced, thereby reducing the total number of verifications in the first program stage, shortening program time of the memory, and improving the performance of the memory by: at the first program stage, performing the first number of the program operations on the memory cells of the target group comprising the first memory cells and the second memory cells, which have different target program states, then performing the verify operation using the verify voltage for the target group; after the second memory cells pass the verification that uses the verify voltage for the target group, performing the second number of the program operations on the second memory cells, and inhibiting the second memory cells from being verified.

In some examples, after the operation method of the memory provided in FIG. 5 is performed, at the second program stage, the program operation and corresponding verify operation may be performed on the memory cells of the target group, to make the memory cells of the target group programmed to the corresponding target program states, i.e., fine programming is performed on the memory cells of the target group, which may, for example, be referred to threshold voltage distribution corresponding to the fine programming shown by using a QLC as an example in FIG. 13.

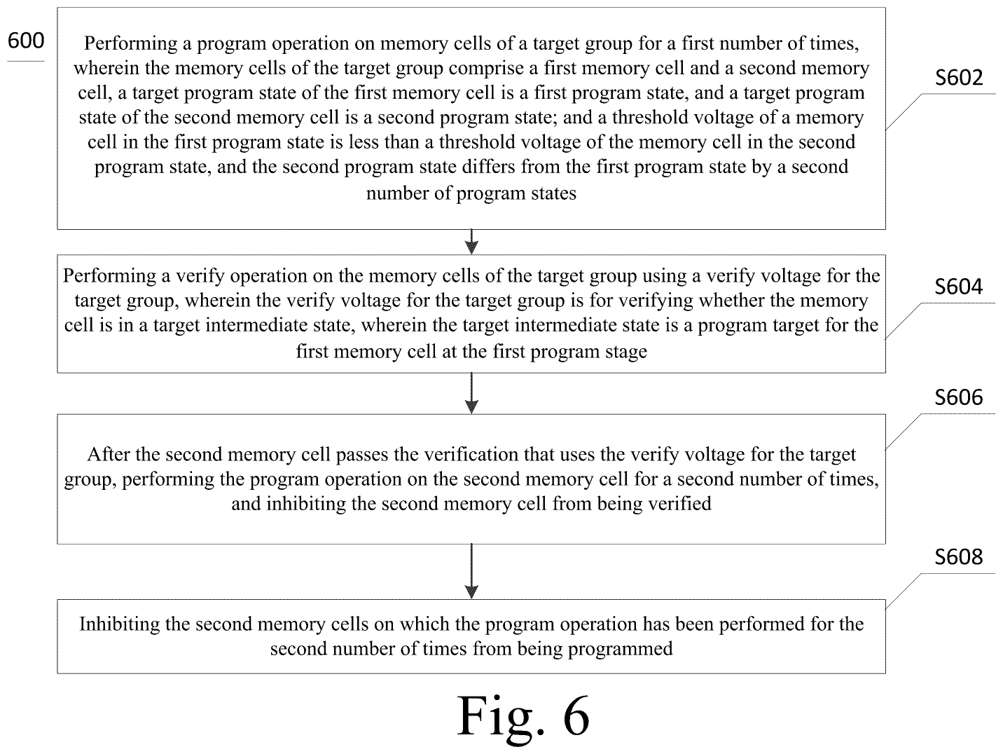

FIG. 6 is a flow diagram of another operation method of a memory shown according to an example. FIG. 6 shows an example that the threshold voltage corresponding to the target program state of the first memory cell (smaller than the threshold voltage of the second memory cell) is selected as the verify voltage for the target group in FIG. 5, and the number of program states by which the second program state and the first program state differ is the same as the number of times of the program operation performed on the second memory cells that pass the verification of the verify voltage for the target group. Referring to FIG. 6, the method 600 provided by the examples of the present disclosure may comprise operation S602 to operation S608 performed at the first program stage.

In operation S602, performing a program operation on memory cells of a target group for a first number of times, wherein the memory cells of the target group comprise a first memory cell and a second memory cell, a target program state of the first memory cell is a first program state, and a target program state of the second memory cell is a second program state; and a threshold voltage of the memory cell in the first program state is less than a threshold voltage of the memory cell in the second program state, and the second program state differs from the first program state by a second number of program states.

In operation S604, performing a verify operation on the memory cells of the target group using a verify voltage for the target group, wherein the verify voltage for the target group is for verifying whether the memory cell is in a target intermediate state, and the target intermediate state is a program target for the first memory cell at the first program stage.

In operation S606, after the second memory cell passes the verification that uses the verify voltage for the target group, performing the program operation on the second memory cell for a second number of times, and inhibiting the second memory cell from being verified.

In some examples, a particular example of operation S606 may be referred to operation S506.

In operation S608, inhibiting the second memory cells on which the program operation has been performed for the second number from being programmed.

In some examples, at a program time period after the second number of program operations is performed in the first program stage, a program inhibit voltage may be applied to the bit line coupled with the second memory cells on which the program operation has been performed for the second number, so as to inhibit programming. The program inhibit voltage, for example, may be a high voltage, and may be much higher than a bias voltage applied to the bit line during programming or verification. For example, in FIG. 10B, at a time period t39, a high voltage V_h applied to the bit line of a P4′ memory cell 1 and a P4′ memory cell 2 is the program inhibit voltage.

According to the operation method of the memory provided by the examples of the present disclosure, at the first program stage, the first number of program operations is performed on the memory cells of the target group that comprise the first memory cells and the second memory cells, which differ by the second number of program states (i.e. differ by the second number of intermediate states), then the verify operation is performed using the verify voltage corresponding to the first intermediate state; and after the second memory cells pass the verification that uses the verify voltage corresponding to the first intermediate state, the second number of program operations are performed on the second memory cells without verification, and then the programming of the second memory cells is stopped. Since the number of program pulses “touch-typed” to the second memory cells that pass the verification that uses the verify voltage for the target group is the same as the number of program states by which the second program state and the first program state differ, it may ensure that the second memory cells are programmed to the target state desired for the second memory cells at the first program stage, such that the number of verifications performed on the second memory cells is reduced with minimum loss of reliability, thereby reducing the total number of verifications performed at the first program stage, shortening program time of the memory, and improving the performance of the memory.

FIG. 7 is a flow diagram of yet another operation method of a memory shown in FIGS. 5 and 6. Differences between FIG. 7 and FIGS. 5 and 6 lie in that, FIG. 7 further shows subsequent operations on the memory cells that do not pass the verification that uses the verify voltage for the target group, and subsequent operations on the first memory cells that pass the verification that uses the verify voltage for the target group. Referring to FIG. 7, the method 700 provided by the examples of the present disclosure may comprise operation S702 to operation S70104 performed at the first program stage.

In operation S702, performing the program operation on the memory cells of the target group for the first number of times.

In some examples, a particular example of operation S702 may be referred to operation S502.

In operation S704, performing the verify operation on the memory cells of the target group using the verify voltage for the target group.

In some examples, a particular example of operation S704 may be referred to operation S504.

In operation S7062, for the memory cells in the target group that do not pass the verification that uses the verify voltage for the target group, continuing performing the program operation.

In operation S7064, after performing the program operation, continuing performing the verify operation using the verify voltage for the target group.

In some examples, operation S7062 and operation S7064 may be performed cyclically, until all the memory cells of the target group pass the verification that uses the verify voltage for the target group or a predetermined ratio (e.g. 90%, 95%, or the like) of the memory cells pass the verification, then continue performing operation S7082 on the first memory cells therein, and operation S70102 is continuously performed on the second memory cells therein.

In operation S7082, after the first memory cell passes the verification that uses the verify voltage for the target group, inhibiting the first memory cell from being programmed.

In some examples, at a program time period after the first memory cell passes the verification that uses the verify voltage for the target group at the first program stage, a program inhibit voltage may be applied to the bit line coupled with the first memory cell that passes the verification that uses the verify voltage for the target group, so as to inhibit programming. The program inhibit voltage may be a high voltage, and may be much higher than a bias voltage applied to the bit line during programming or verification.

In operation S70102, after the second memory cell passes the verification that uses the verify voltage for the target group, performing the program operation on the second memory cell for a second number of times, and inhibiting the second memory cell from being verified.

In some examples, a particular example of operation S70102 may be referred to operation S506.

In operation S70104, inhibiting the second memory cell on which the program operation has been performed for the second number from being programmed.

In some examples, a particular example of operation S70104 may be referred to operation S608.

According to the operation method of the memory provided by the examples of the present disclosure, at the first program stage, the program operation is performed on the memory cells of the target group comprising the first memory cell and the second memory cell (which have different target program states) for the first number of times, then the verify operation using the verify voltage for the target group is performed. After continue programming the memory cells of the target group that do not pass the verification, continue performing the verify operation using the verify voltage for the target group, until the memory cells pass the verification, then inhibiting the first memory cell that passes the verification from being programmed. The program operation is performed on the second memory cell that passes the verification for the second number of times without verification, and then the programming of the second memory cell is stopped, thus the number of verifications performed on the second memory cell is reduced, the total number of verifications in the first program stage is reduced, thereby shortening program time of the memory, and improving the performance of the memory.

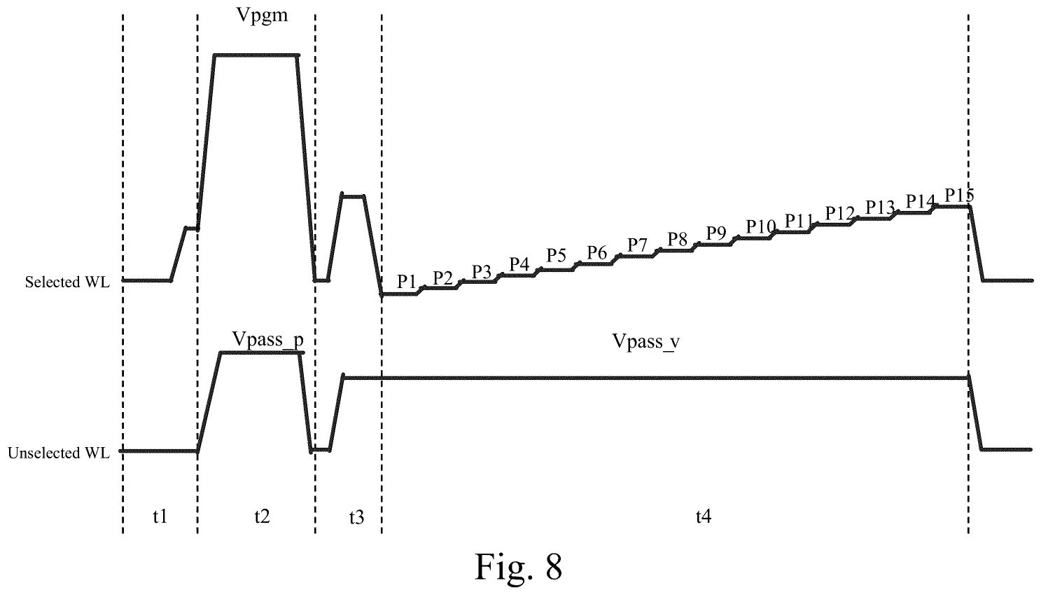

In FIGS. 8 and 9, the examples of the present disclosure and some examples are compared and described by taking an example that the memory is a QLC NAND flash memory. A QLC-type memory cell may have 16 states after fine programming, which may be, for example, represented as P0, P1, P2, P3, . . . , P14, and P15 in the order of threshold voltages from small to large, wherein P0 is an erased state, and there are 15 program states P1-P15 in total. Accordingly, after coarse programming, there are 15 intermediate states P1′-P15′ in total. A correspondence relationship between the 15 intermediate states at a coarse program stage and the 15 program states at a fine program stage may be referred to FIG. 13.

FIG. 8 shows a schematic waveform diagram of word line voltages of a QLC NAND flash memory at a first program stage in some examples. As shown in FIG. 8, at a program time period t2 after a pre-charging time period t1, a program voltage Vpgm is applied to a selected word line, and a program pass voltage Vpass_p is applied to an unselected word line, so as to program the memory cells to be programmed coupled with the selected word line, and not program the memory cells coupled with the unselected word line. At a time period t4 after a pre-pulse time period t3 after the program time period t2,, the verify voltages (e.g., may be represented as vpv_p1', vpv_p2′, . . . , and vpv_p15′, which are correspondingly labeled using the identifiers of intermediate states in FIG. 8) corresponding to P1′-P15′ are respectively employed for verification, i.e. 15 levels of the verify voltages for verification are applied to the selected word line (FIG. 8 is for illustrative purposes only, and possible program voltages are omitted from the two verify voltages therein), and a verify pass voltage Vpass_v is applied to the unselected word line correspondingly (indicating not to verify the memory cells coupled with the unselected word line). For example, for the memory cells of which program target is P1′ at the first program stage, the verify voltage vpv_p1′ is employed for verification; for the memory cells of which program target is P2′ at the first program stage, after the verify voltage vpv_p1′ is employed for verification and the verification is passed, then after one or more program time periods, the verify voltage vpv_p2′ is employed for verification, . . . , then for the memory cells of which program target is Pm′ at the first program stage, when m>1, a total of m verify voltages comprising vpv_p1′, vpv_p2′, . . . , and vpv pm′ are employed at the verify time period.

The operation method of the memory provided in FIG. 5 is applied to the QLC NAND flash memory. For example, the memory cells having 15 target program states that are to be programmed in the memory are divided into 4 groups in an order from the minimum to maximum threshold voltages corresponding to the target program states. FIG. 9 provides a particular way for grouping verification: the memory cells in the 1st to 3rd group have 4 target program states, the memory cells in the 4th group have 3 target program states, and the target group is any one of the 1st to 4th group. For the selection of the verify voltage of each group, if the memory cells in the target group have i (i is an integer greater than 1, and in FIG. 9, i is 4 or 3) target program states, the first program state is the target program state corresponding to the minimum threshold voltage among the i target program states, and the second program state is any one of the i target program states other than the target program state corresponding to the minimum threshold voltage, such that the verify voltage same as that of the first intermediate state may be selected as the verify voltage for each group. The following is illustrated in conjunction with FIG. 9.

FIG. 9 is a schematic waveform diagram of word line voltages of a QLC NAND flash memory at a first program stage shown by examples of the present disclosure. Differences between FIG. 9 and FIG. 8 lie in that, after a pre-charging time period t11, a program time period t12, and a pre-pulse time period t13, at a time period t14, verification is performed according to the divided groups, wherein for the 1st group comprising the memory cells of which program targets are P1′-P4′ at the first program stage, the verify voltage vpv_p1′ corresponding to P1′ is employed for verification; for the 2nd group comprising the memory cells of which program targets are P5′-P8′ at the first program stage, the verify voltage vpv_p5′ corresponding to P5′ is employed for verification; at a time period t15, programming may be continued. FIG. 9 is illustrative only, and the number of times for programming and the number of times for verification may both be designed according to actual situations. At a time period t16, for the 3rd group comprising the memory cells of which program targets are P9′-P12′ at the first program stage, the verify voltage vpv_p9′ corresponding to P9′ is employed for verification; and for the 4th group comprising the memory cells of which program targets are P13′-P15′ at the first program stage, the verify voltage vpv_p13′ corresponding to P13′ is employed for verification. Therefore, comparing FIG. 9 applying the method provided by the examples of the present disclosure with FIG. 8, for the memory cells of which program target is Pm′ at the first program stage, when m>1, the number of different verify voltages employed at the verify time period is reduced by at least m-1, such that the number of verifications performed at the first program stage is significantly reduced, and the total time of the first program stage is greatly shortened.

FIG. 10A is a flow diagram of still another operation method of a memory shown according to an example. The correlation between FIG. 10A and FIG. 5 is that FIG. 10A illustrates the method shown in FIG. 5 in terms of how voltages are applied to word (and bit) lines over different time periods.

Referring to FIG. 10A, the method 1000 provided by the examples of the present disclosure may comprise the following operations.

In operation S10032, at the first program stage, performing the program operation on target memory cells coupled with the selected word line, wherein the target memory cells comprise the memory cells of the target group. Operation S10032 may comprise operation S100322 and operation S100324. The explanation for the memory cells of the target group may be referred to operation S502, and the memory cells of the target group comprise the first memory cells and the second memory cells is used as an example for description.

In operation S100322, within a first time period, applying a program voltage to the selected word line for a first number of times, and applying the verify voltage for the target group to the selected word line. Operation S100322 may be an operation, corresponding to operation S502 and operation S504, of applying the voltage to the word line.

In some examples, at each program time period of applying the program voltage to the selected word line, an intermediate voltage (e.g. V_3BL in FIG. 10B) or a ground voltage (e.g. 0 V) may be applied to the bit line coupled with the memory cells of the target group that do not pass the verification, so as to perform the program operation on the memory cells of the target group. For the current first memory cells that pass the verification, the program inhibit voltage (for example, which may be a high voltage) may be applied to the bit line coupled with these memory cells at the program time period, so as to stop programming the first memory cells. For the current second memory cell that passes the verification, operation S100324 is performed.

In some examples, the verify voltage for the target group may be applied to the selected word line after applying the program voltage to the selected word line each time, i.e. each program time period is followed by one verify time period. The verify voltage (e.g. the voltage applied to the bit line coupled with P4 memory cells 1-4 at a time period t32 in FIG. 10B) may be applied to the bit line coupled with the memory cells of the target group that currently do not pass the verification at each verify time period, so as to verify the memory cells of the target group that currently do not pass the verification. For the memory cells of the target group that currently pass the verification, the verify inhibit voltage (for example, 0 V applied to the bit line of the P4 memory cells 1 and 2 at a time period t34 in FIG. 10B is the verify inhibit voltage) may be applied to the bit line coupled with these memory cells at the verify time period.

In operation S100324, within a second time period after the first time period, applying a program voltage to the selected word line for a second number of times, and applying the verify voltage for the target group to the selected word line.

In some examples, when the second number of program voltages is applied to the selected word line within the second time period, the intermediate voltage or ground voltage may be applied to the bit line coupled with the second memory cells that pass the verification that uses the verify voltage for the target group, such that the second number of program operations that are performed on the second memory cells in operation S506 can be implemented.

In some examples, within the second time period, between at least two applications of the program voltage during applying the program voltage to the selected word line for the second number of times, while applying the verify voltage for the target group on the selected word line, the verify inhibit voltage may be applied to the bit line coupled with the second memory cells that pass the verification that uses the verify voltage for the target group, such that, at the verify time period after each program operation, the memory cells of the target group that do not pass the verification that uses the verify voltage for the target group may be verified, without verifying the second memory cells (and the first memory cells) that pass the verification that uses the verify voltage for the target group. Therefore, the program pulses are “touch-typed” to the second memory cells that pass the verification that uses the verify voltage for the target group, and the number of verifications is reduced while ensuring that the second memory cells are programmed to the target state desired for the second memory cells at the first program stage.

In FIG. 10B, the operation of grouping the memory cells of the QLC NAND flash memory according to the method provided by the examples of the present disclosure, and then applying the voltage to the memory cells of the 1st group of which program targets comprises four intermediate states P1′, P2′, P3′, and P4′ at the first program stage is used as an example for description. For example, according to the above, 15 intermediate states are divided into 4 groups based on the number of intermediate states being 4-4-4-3 in order. FIG. 10B shows a voltage waveform diagram of applying an operation method of a memory of examples of the present disclosure according to FIG. 10A. In FIG. 10B, an ISPP scheme is employed for programming, i.e. the program voltages increasing in a fixed step size are applied in a cycle M, a cycle M+1, a cycle M+2, . . . , and a voltage waveform of the bit line coupled with the memory cells of the 1st group and a voltage waveform of the total of 4 memory cells 1-4 (hereinafter referred to as P4′ memory cells) of which program target is P4′ are shown at the first program stage.

As shown in FIG. 10B, at a time period t31, the program operation of the Mth cycle is performed, the program voltage is applied to the selected word line, and 0 V or V_3BL (intermediate voltage) is applied to the bit line coupled with the P4′ memory cells 1-4, indicating that the program operation is currently performed on all 4 P4′ memory cells. A 2BL programming or 3BL programming scheme may be employed. The 2BL programming scheme refers to a programming scheme that two voltage levels of a low voltage (e.g. 0 V) and a high voltage may be applied to the corresponding bit line, wherein the low voltage corresponds to the program operation, and the high voltage corresponds to the inhibiting of programming. The 3BL programming scheme refers to a programming scheme that three voltage levels of a low voltage, an intermediate voltage, and a high voltage may be applied to the corresponding bit line, wherein the low voltage or the intermediate voltage corresponds to the program operation, and the high voltage corresponds to the inhibiting of programming. At the time period t32, the verify operation after the program operation of the Mth cycle is performed, vpv_p1′ is applied to the selected word line, and the verify voltage is applied to the bit line coupled with the P4′ memory cells 1-4, so as to verify whether the current threshold voltages of the P4′ memory cells 1-4 are greater than vpv_p1′.

During the verify operation at the time period t32, the P4′ memory cells 1 and 2 pass the verification (1002 and 1006), and since P4′ and P1′ corresponding to vpv_p1′ differ by 3 program states, the program operation is performed on the P4′ memory cell 1 and the P4′ memory cell 2 for 3 times at time periods t33, t35, and t37 (1004), and the verify inhibit voltage (0 V) is applied to the bit line coupled with the P4′ memory cell 1 and the P4′ memory cell 2 at time periods t34, t36, and t38, i.e. 3 program pulses are respectively “touch-typed” to the P4′ memory cells 1 and 2 that pass the verification that uses the verify voltage vpv_p1′. Then at a time period t39, when the program operation of the (M+4)th cycle is performed, the program inhibit voltage V_h is applied to the bit line coupled with the P4′ memory cell 1 and the P4′ memory cell 2, i.e. after 3 program pulses are “touch-typed” to the P4′ memory cells 1 and 2 that pass the verification that uses the verify voltage vpv_p1′, the programming of the P4′ memory cells 1 and 2 is stopped.

During the verify operation of the time period t32, the P4′ memory cells 3 and 4 do not pass the verification, and at the time period t33, the P4′ memory cells 3 and 4 are continuously programmed during the program operation of the (M+1)th cycle, i.e. 0 V or V_3BL is applied to the bit line coupled with the P4′ memory cells 3 and 4. At the time period t33, the verify operation after the program operation of the (M+1)th cycle is performed, vpv_p1′ is still applied to the selected word line, and the verify voltage is applied to the bit line coupled with the P4′ memory cells 3 and 4. In this case, the P4′ memory cells 3 and 4 pass the verification (1008 and 10012), the program operation is performed on the P4′ memory cell 3 and the P4′ memory cell 4 for 3 times at time periods t35, t37, and t39, and at three verify time periods (not shown in the figure) after t36, t38, and t39, the verify inhibit voltage (0 V) is applied to the bit line coupled with the P4′ memory cell 3 and the P4′ memory cell 4, i.e. 3 program pulses are respectively “touch-typed” to the P4′ memory cells 3 and 4 that pass the verification that uses the verify voltage vpv_p1′.

According to the method provided by the examples of the present disclosure, the memory cells are divided into the plurality of target groups according to different target program states, and at the first program stage of the memory cells of each target group, only the verify voltage corresponding to one intermediate state is employed during the application of the first several program pulses to the selected word line, such that the number of verifications performed in the first program stage is reduced, thereby shortening program time.

FIG. 11 shows a schematic diagram of distribution of threshold voltages of second memory cells after a second number of program operations. Referring to FIG. 10B, the P1′ memory cells in the 1st group with the P4′ memory cells 1-4 may correspond to the first memory cells in the method provided in FIG. 5, and the P4′ memory cells 1-4 may correspond to the second memory cells in the method provided in FIG. 5.

A horizontal axis in FIG. 11 indicates the magnitude of the threshold voltage, and a longitudinal axis (not shown) indicates the number of memory cells. As shown in FIG. 11, P4′ PVS is a voltage interval in which the threshold voltages of the P4′ memory cells (comprising 1-4) are located before the P1′ verify voltage (vpv_p1′) is employed to verify the P4′ memory cells. After the P4′ memory cells are verified and pass the verification, the threshold voltages of the P4′ memory cells are distributed between a point A and a point B. For example, the point A may indicate the threshold voltage that is obtained by verifying the P4′ memory cell 1 after the program voltage of the cycle M is applied, and the point B may indicate the threshold voltage that is obtained by verifying the P4′ memory cell 2 after the program voltage of the cycle M+1 is applied. The program voltage is applied for three times to the P4′ memory cells that pass the verification that uses vpv_p1′ without verification, thus the displacement of the threshold voltages of the P4′ memory cell 1 and the P4′ memory cell 2 under an ideal condition may be obtained through calculation: [(vpgm@pulseM+3)−(vpgm@pulseM)]=ISPP_step*3, and [(vpgm@pulseM+4)−(vpgm@pulseM+1)]=ISPP_step*3, wherein vpgm@pulseM represents a program pulse voltage value of the cycle M, vpgm@pulseM+3 represents a program pulse voltage value of the cycle M+3, vpgm@pulseM+1 a program pulse voltage value of the cycle M+1, vpgm@pulseM+4 represents a program pulse voltage value of the cycle M+4, and ISPP_step represents an increased step size in the ISPP solution. In FIG. 11, according to the threshold voltage displacement calculated under the ideal condition, the threshold voltage of the P4′ memory cell 1 moves from the point A to a point A1, and the threshold voltage of the P4′ memory cell 2 moves from the point B to a point B1.

In some examples, since the threshold voltages of the memory cells during an actual operation may change within a short time, short time variation factors of the threshold voltages may be taken into consideration when the displacement of the threshold voltages of the P4′ memory cell 1 and the P4′ memory cell 2 is calculated after the program voltage is applied for three times. For example, a short time variation slope of the threshold voltage could be multiplied therewith, i.e. the displacements of the threshold voltages of the P4′ memory cell 1 and the P4′ memory cell 2 are respectively: [(vpgm@pulseM+3)−(vpgm@pulseM)]*slope−ISPP_step*3*slope, and [(vpgm@pulseM+4)−(vpgm@pulseM+1)]*slope =ISPP_step*3*slope, wherein the slope is between 0.6 and 1, for example, may be 0.8. In FIG. 11, according to the displacements of the threshold voltages calculated by taking the short time variation factors of the threshold voltages into consideration, the threshold voltage of the P4′ memory cell 1 moves from the point A to a point A2, and the threshold voltage of the P4′ memory cell 2 moves from the point B to a point B2.

According to the threshold voltage distribution of the second memory cells provided by the examples of the present disclosure after the second number of program operations, by employing the operation method of the memory provided by the examples of the present disclosure, the second memory cells may be programmed to the target state desired for the second memory cells at the first program stage by “touch-typing” the program pulses to the second memory cells that pass the verification that uses the verify voltage for the target group, such that the loss of reliability is minimal.

FIG. 12 shows another schematic diagram of distribution of threshold voltages of second memory cells after a second number of program operations. In FIG. 12, the P1′ memory cells in the 1st group may correspond to the first memory cells in the method provided in FIG. 5, and P2′, P3′, and P4′ memory cells may all correspond to the second memory cells in the method provided in FIG. 5.

As shown in FIG. 12, P1′/P2′/P3′/P4′ PVS is a voltage interval in which the threshold voltages of the P1′, P2′, P3′, and P4′ memory cells are located before the P1′ verify voltage (vpv_p1′) is employed to verify the memory cells of the 1st group. After the memory cells of the 1st group are verified and pass the verification, the P1′ memory cells are inhibited from being programmed (for example, the program inhibit voltage may be applied to the bit line coupled with the P1′ memory cells), 1 program voltage is then applied to the P2′ memory cells without verification, 2 program voltages are then applied to the P3′ memory cells without verification, and 3 program voltages are then applied to the P4′ memory cells without verification. Referring to FIG. 12, on a threshold voltage axis and on the right side of the P1′ verify voltage, it is shown the threshold voltage distribution of the P1′ memory cells that pass the verification that uses vpv_p1′, and the threshold voltage distributions of the P2′, P3′, and P4′ memory cells that are obtained through calculation by employing any one of the methods in FIG. 11.

The threshold voltage distributions of the P1′, P2′, P3′, and P4′ memory cells in FIG. 12 are illustrative only, and in a practical application, when a large number of QLC memory cells are operated, the threshold voltage distributions of the memory cells of every two adjacent intermediate states after the programming of the first program stage may have overlapping parts.

According to the threshold voltage distribution of the second memory cells provided by the examples of the present disclosure after the second number of program operations, by employing the operation method of the memory provided by the examples of the present disclosure, the program pulses are “touch-typed” to the second memory cells that pass the verification that uses the verify voltage for the target group, and for the second memory cells comprising different target program states, the second memory cells may be programmed to the target state desired for the second memory cells at the first program stage, such that the loss of reliability is minimal.

FIG. 13 shows a schematic diagram of distribution of threshold voltages of memory cells obtained after an operation is performed on a QLC NAND memory by employing a method provided by examples of the present disclosure. As shown in FIG. 13, before entering the program stage, all the memory cells to be programmed are in an erased state, and the threshold distribution interval is the widest currently. At the coarse program stage, the method provided by the examples of the present disclosure is employed, by “touch-typing” the program pulses after the memory cells of each group are verified by only utilizing the verify voltage corresponding to the minimum program state of the group after programming at the coarse program stage, according to the calculation method of the threshold voltage displacement in FIG. 11, the memory cells may be programmed to 16 widely-distributed threshold voltage intervals shown in FIG. 13, and the 16 interval distributions along the horizontal axis from left to right correspond to an erased state P0′ and 15 intermediate states P1′, P2′, P3′ . . . P14′, and P15′ on a one-to-one basis. Then at the fine program stage (i.e. the above-mentioned second program stage), the memory cells are programmed to 16 narrowly-distributed threshold voltage intervals, and the 16 interval distributions along the horizontal axis from left to right correspond to an erased state P0 and 15 program states P1, P2, P3 . . . P14, and P15, wherein the states having the same numbers at the coarse program stage correspond to the same memory cells. Therefore, by employing the method provided by the examples of the present disclosure, the total number of verifications at the first program stage is reduced with minimum loss of reliability, thereby shortening the total program time of the memory, and improving the performance of the memory.

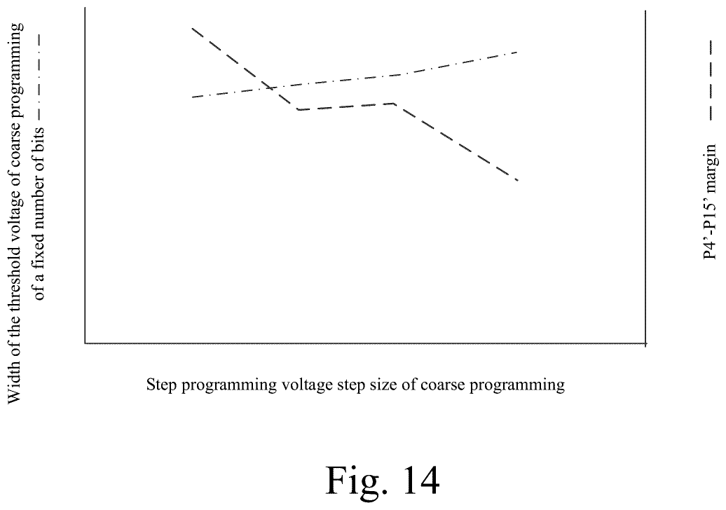

FIG. 14 shows a trend diagram of indexes obtained after a test operation is performed on a QLC NAND memory by employing a method provided by examples of the present disclosure. Two index values after each coarse program stage are obtained by employing the method provided by examples of the present disclosure to perform coarse programming for a plurality of times in the QLC NAND memory: a width of the threshold voltage distribution interval of the memory cells of a fixed number of bits (which, for example, may be 100 bits), and a threshold voltage margin of the intermediate states P4′-P15′. As shown in FIG. 14, an ISPP step size at the coarse program stage is used as an independent variable, and the width of the threshold voltage distribution interval of the memory cells of the fixed number of bits increases with increasing ISPP step sizes; and the threshold voltage margin of the program states P4-P15 reduces with increasing ISPP step sizes firstly, then basically remains unchanged within a range of the ISPP step sizes, and then reduces with increasing ISPP step sizes again.

According to the trend diagram of indexes provided by the examples of the present disclosure, in the practical application, suitable ISPP step sizes may be selected according to requirements when the method provided by the examples of the present disclosure is implemented, so as to shorten the program time of the memory while the width of the threshold voltage distribution interval for the fixed number of bits and the threshold voltage margin are optimized.

In FIG. 10B, the verification is illustrated by employing the verify voltage for only one target group (the first group) for verification during the verify time period after one program pulse. In some other examples, the verify voltages for the plurality of target groups may also be employed for verification at the verify time period after one program pulse. For example, FIG. 15 shows an example that the verify voltages for two target groups are employed for verification at the verify time period after one program pulse.

FIG. 15 is another schematic waveform diagram of word line voltages of a QLC NAND flash memory at a first program stage shown by examples of the present disclosure, wherein only the waveform of a selected word line voltage is shown. In FIG. 15, for example, the memory cells in the memory that are to be programmed to 15 intermediate states at the first program stage are divided into 5 groups according to an order from the minimum to maximum threshold voltages corresponding to the intermediate states. The number of program states of each group is 3-4-4-2-2 in order, i.e. the 1st group comprises the memory cells of which program targets at the first program stage are P1′, P2′, and P3′, the 2nd group comprises the memory cells of which program targets at the first program stage are P4′, P5′, P6′, and P7′, the 3rd group comprises the memory cells of which program targets at the first program stage are P8′, P9′, P10′, and P11′, the 4th group comprises the memory cells of which program targets at the first program stage are P12′ and P13′, and the 5th group comprises the memory cells of which program targets at the first program stage are P14′ and P15′.

As shown in FIG. 15, after the program pulse of a cycle N is applied at a time period t41, and after the memory cells of the 2nd group are verified using the verify voltage for the 2nd group at a time period t42, the memory cells of the 3rd group may be verified using the verify voltage for the 3rd group at a time period t43, wherein the verify voltage for the 2nd group, for example, may be the verify voltage vpv_p4′ corresponding to P4′, and the verify voltage for the 3rd group, for example, may be the verify voltage vpv_p8′ corresponding to P8′. That is, at the verify time periods t42+t43 after the program time period t41, the memory cells of the 2nd group and the memory cells of the 3rd group are verified by respectively employing the verify voltage for the 2nd group and the verify voltage for the 3rd group.

Similarly, after the program pulse of a cycle N+1 is applied at a time period t44, and after the memory cells of the 3rd group are verified using the verify voltage (e.g. vpv_p8′) for the 3rd group at a time period t45, the memory cells of the 4th group may be verified using the verify voltage (which, for example, may be the verify voltage vpv_p12′ corresponding to P12′) for the 4th group at a time period t46. Then the program pulse of a cycle N+2 is applied at a time period t47, and the memory cells that do not pass the verification are continuously programmed.

According to the method provided by the examples of the present disclosure, by employing the operation method of the memory provided by the examples of the present disclosure, during the program operation at the first program stage, after a certain number of program cycles are performed, the memory cells of the plurality of adjacent groups may be verified between two program cycles by using the verify voltages for the respective groups, such that the total time of the first program stage is further shortened.

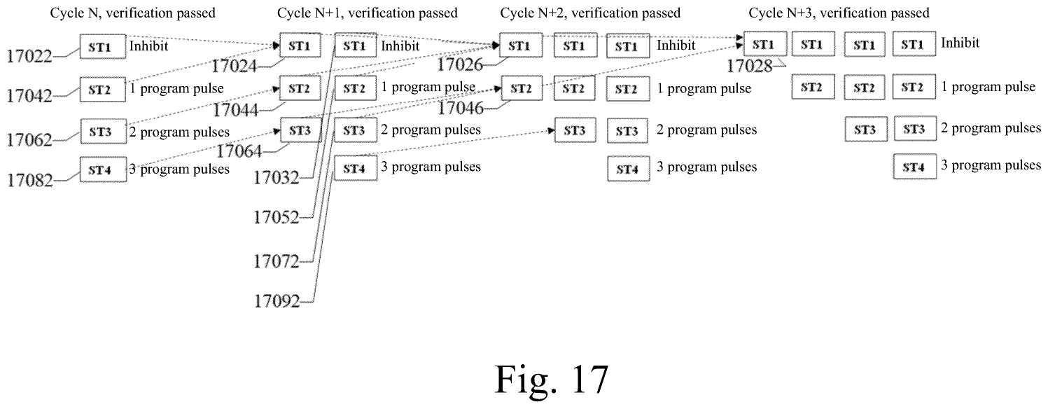

The following describes how the operation method of the memory provided by embodiments of the present disclosure is implemented by peripheral circuit. Referring to FIG. 4, a page buffer circuit in the peripheral circuit may comprise a plurality of latch circuits (which, for example, may be latches), and selection, judgment, and the like operations in the method may be implemented by using the latch circuits to store identifiers (consisting of “0” and “1”) corresponding to information such as sequences, states, results, etc. Using the operation method of the memory shown in FIG. 5 as an example, in operation S502 and operation S504, the memory cells of the target group may be selected according to group identification information of the corresponding target group to which the memory cells belong, which is stored in the latch circuit, so as to perform corresponding program and verify operations on the memory cells. In operation S504, the set corresponding verify voltage may also be obtained according to the group identification information, so as to perform the verify operation on the memory cells of the target group using the verify voltage for the target group. The target program state of one memory cell may be determined according to the group identification information and to-be-programmed state identification information stored in the latch circuit. After the memory cells are determined as the second memory cells in operation S506, whether the verification is passed according to the results stored in the latch circuit (for example, “1” indicates pass, and “0” indicates not pass) of performing the verify operation. After the second memory cells pass the verification that uses the verify voltage for the target group, the second number of program operations are performed on the second memory cells. FIGS. 16 and 17 show an information processing method of the latch circuit for performing the second number of program operations on the second memory cells using a QLC as an example.

FIG. 16 shows a schematic diagram of each program state (or intermediate states in one-to-one correspondence with the program states) of a QLC memory cell indicated by group identification information and information of a state to be programmed. In FIG. 16, 15 program states are divided into 4 groups according to the number of program states being 4-4-4-3. As shown in FIG. 16, VPV1 16002, VPV2 16004, VPV3 16006, and VPV4 16008 represent the verify voltages for the 1st, 2nd, 3rd, and 4th groups in sequence, which may respectively correspond to 4 pieces of group identification information, for example, 00, 01, 10, and 11 may respectively correspond to VPV1 16002 (i.e. vpv_p1′), VPV2 16004 (i.e. vpv_p5′), VPV3 16006 (i.e. vpv_p9′), and VPV4 16008 (i.e. vpv_p13′). That is, based on the way of grouping in FIG. 16, the group identification information comprises 2 bits and may be stored by utilizing 2 latches.

ST1, ST2, ST3, and ST4 may be used to indicate four states to be programmed, wherein ST1 represents a program inhibit state, i.e. programming is not performed on the corresponding memory cells at the next program pulse; ST2 represents 1 “touch-typed” program pulse remaining, i.e. programming is performed on the corresponding memory cells at the next program pulse without verification; ST3 represents 2 “touch-typed” program pulses remaining, i.e. programming is performed on the memory cells at the next two continuous program pulses without verification; and ST4 represents 3 “touch-typed” program pulses remaining, i.e. programming is performed on the memory cells at the next three continuous program pulses without verification. The number of states to be programmed corresponding to the memory cells in the four groups in FIG. 16 is up to 4, thus also comprises 2 bits and may be stored by utilizing 2 latches.

If 15 target program states of the memory cells, which pass the verification that uses the verify voltages for the respective groups and on which the second number of program operations have not been performed (or not to be performed), are indicated in FIG. 16, in the 1st group passing the verification that uses VPV1 16002, ST1 16022 indicates the memory cells of which target program states are P1 (i.e. the program target at the first program stage is P1′, similarly below), ST2 16024 indicates the memory cells of which target program states are P2, ST3 16026 indicates the memory cells of which target program states are P3, and ST4 16028 indicates the memory cells of which target program states are P4; and in the 2nd group passing the verification that uses VPV2 16004, ST1 16042 indicates the memory cells of which target program states are P5, ST2 16044 indicates the memory cells of which target program states are P6, ST3 16046 indicates the memory cells of which target program states are P7, and ST4 16048 indicates the memory cells of which target program states are P8; and the 3rd group passing the verification that uses VPV3 16006 and the 4th group passing the verification that uses VPV4 16008 are arranged in sequence.

When operation S506 is performed, the second memory cells to be programmed (without verification) and the corresponding second number may be determined firstly according to VPVx and Sty (x,y∈[1,4]) shown in FIG. 16, wherein the memory cells corresponding to Sty when y>1 are the second memory cells. For example, when x=1 and y=2, VPV1 16002 and ST2 16024 are the second memory cells on which the program operation is to be performed once; and when x=2 and y=3, VPV2 16004 and ST3 16046 are the second memory cells on which the program operation is to be performed twice. After performing the program operation one time during performing the program operation for the second number of times, the to-be-programmed state identification information stored in the corresponding latch circuits is updated, i.e. Sty is updated to Sty-1. For example, whether the program operation is to be performed next time on the second memory cells (y−1>1) or the second memory cells are to be inhibited from being programmed (y−1=1) is then determined according to the updated to-be-programmed state identification information.

FIG. 17 shows a method for updating to-be-programmed state identification information during a process of applying several program pulse voltages according to FIG. 16. In FIG. 17, the process is illustrated using the example of verifying using the verify voltage for the same group of memory cells having four target program states in total after each program pulse, which may correspond to the voltage waveform in FIG. 10B. As shown in FIG. 17, the memory cells of the group passing the verification after the program pulse of the cycle N are divided into four states to be programmed: ST1 17022, ST2 17042, ST3 17062, and ST4 17082, which correspond to the program inhibit state, 1 “touch-typed” program pulse remaining, 2 “touch-typed” program pulses remaining, and 3 “touch-typed” program pulses remaining in sequence. During the application of the program pulse of the cycle N+1, the corresponding memory cells are inhibited from being programmed according to ST1 17022, and the program operation is performed on the corresponding memory cells according to ST2 17042, ST3 17062, and ST4 17082. Then, information in the latch storing ST2 17042, ST3 17062, and ST4 17082 is correspondingly updated to ST1 17024, ST2 17044, and ST3 17064 (since ST1 17022 and ST1 17024 correspond to the same binary data, the information in the latch corresponding to ST1 17022 does not need to be updated, i.e. the corresponding memory cells remain inhibited from being programmed). During the verification after the program pulse of the cycle N+1 is applied, the memory cells corresponding to ST1 17024 (and ST1 17022), ST2 17044, and ST3 17064 all are not verified, and the verify voltage for the group is still employed to verify the memory cells of the group that have not passed the verification before. The states to be programmed of the memory cells passing the current verification are stored as ST1 17032, ST2 17052, ST3 17072, and ST4 17092.

During the application of the program pulse of the cycle N+2, the corresponding memory cells are inhibited from being programmed according to ST1 17024 and ST1 17032, and the program operation is performed on the corresponding memory cells according to ST2 17044, ST2 17052, ST3 17064, ST3 17072, and ST4 17092. Then, information in the latch storing ST2 17044 and ST3 17064 is correspondingly updated to ST1 17026 and ST2 17046 (the information in the latch corresponding to ST1 17024 also does not need to be updated), and the information in the latch storing ST2 17052, ST3 17072, and ST4 17092 is updated similarly to the information in the latch storing ST2 17042, ST3 17062, and ST4 17082 in preparation for the cycle N+3. During the verification after the program pulse of the cycle N+2 is applied, the verify voltage for the group is still employed to only verify the memory cells of the group that have not passed the verification before. A process of updating the information of the state to be programmed during the programming of the cycle N+3 follows this pattern. For example, after the memory cells corresponding to ST4 17082, which pass the verification after the program pulse of the cycle N, successively go through the program pulse of the cycle N+1, the program pulse of the cycle N+2, and the program pulse of the cycle N+3, the information stored in the corresponding latches is ST1 17028, i.e. entering the program inhibit state, and the verify operation is not performed during the three program periods.

According to an information processing method of the latch circuit provided by the examples of the present disclosure, the memory cells of the corresponding target group are selected by utilizing the group identification information, which is latched in the latch circuit, of the target group to which the memory cells belong, so as to perform corresponding program and verify operations on the memory cells. Whether the verification is passed is determined according to the results, which are latched in the latch circuit, of performing the verify operation, and then the operation of “touch-typing” the program pulses is performed according to the to-be-programmed state identification information latched in the latch circuit. Therefore, the operation method of the memory provided by the examples of the present disclosure may be implemented by only employing a small number of latch circuits, thus requiring only the design of control logic in the firmware at the system side.

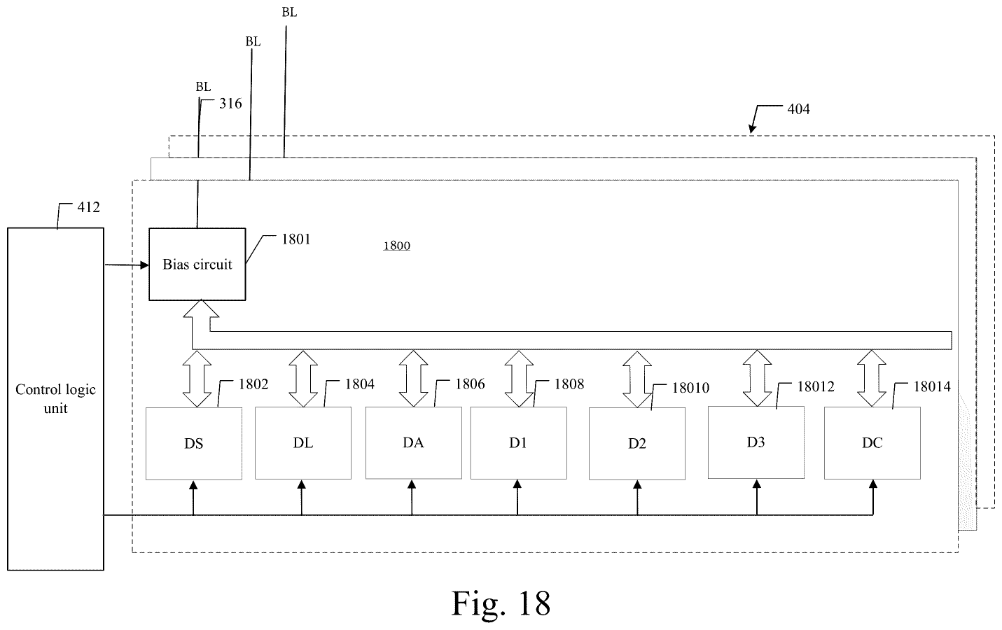

FIG. 18 shows a block diagram of a page buffer/sense amplifier. FIG. 18 may be an example of a page buffer/sense amplifier 404 in FIG. 4, which is configured to implement the method provided by the examples of the present disclosure. As shown in FIG. 18, the page buffer/sense amplifier 404 may comprise a plurality of page buffer circuits 1800. Each page buffer circuit 1800 is coupled to one respective bit line among bit lines 316, i.e., each page buffer circuit 1800 may be coupled to the respective memory string 308 through the corresponding bit line 316, and is configured to temporarily store, during the program operation, fragments of a plurality of bits of data that are used for programming respective selected memory cell (coupled to the selected word line 318 and the bit line 316 coupled with the selected memory cell). FIG. 18 shows 4 data latch circuits D1 1808, D2 18010, D3 18012, and DC 18014. Each data latch circuit, for example, may comprise a latch, and may be configured to temporarily store 4 bits of data to be programmed in the QLC memory cells. It is to be understood that, the number of data latch circuits may be adjusted according to the number of bits of data to be programmed in the memory cells.

Each page buffer circuit 702 may comprise a bias circuit 1801, wherein the bias circuit 1801 is coupled to the respectively bit line 316 and configured to be controlled by a control logic unit 412, thus applying a bit line voltage to the corresponding selected memory cell coupled to the respective bit line 316 during the program operation. Each page buffer circuit 1800 may further comprise a plurality of latch circuits for storing non-data page information (i.e. any information other than the data bit in the data page). As shown in FIG. 18, in some examples, the page buffer circuit 702 may comprise a sensing latch circuit DS 1802 configured to latch data based on a current flowing through the bit line. The page buffer circuit 702 may further comprise a state latch circuit DA 1806 that is configured to latch first result information of performing the verify operation on the memory cells of the target group using the verify voltage for the target group. The page buffer circuit 702 may further comprise a low-voltage latch circuit DL 1804 that is configured to latch second result information of the performed verify operation, for example, configured to latch result information of the performed verify operation after 0 V or V_3BL is applied to the bit line 316.

In the process of performing operation S506 shown in FIG. 17 by utilizing the page buffer circuit 702 shown in FIGS. 18, D1 1808 and D2 18010 (which may be combined and referred to as a first data latch circuit) may be utilized to latch the group identification information corresponding to any one of VPV1 16002, VPV2 16004, VPV3 16006, and VPV4 16008. Also, D3 18012 and DC 18014 (which may be combined and referred to as a second data latch circuit) may be utilized to latch the to-be-programmed state identification information corresponding to any one of ST1, ST2, ST3, and ST4, and DA 1806 may be utilized to latch the first result information of performing the verify operation using the verify voltage for the target group each time, so as to implement the process of performing the second number of program operations on the second memory cells shown in FIG. 17.

According to the page buffer circuit provided by the examples of the present disclosure, the data latch circuit is reused to latch the group identification information and the to-be-programmed state identification information, and the low-voltage latch circuit is utilized to latch the results of performing the verify operation, so as to implement the operation method of the memory provided by the examples of the present disclosure according to the group identification information of the target group to which the memory cells belong, the results of performing the verify operation, and the to-be-programmed state identification information, such that hardware costs may be reduced, and the benefits of improving the performance of the memory are much greater than the costs incurred.

In some examples, other grouping methods may be employed for the QLC memory cells, and when other grouping methods are employed, the operation method of the memory provided by the examples of the present disclosure may be similarly implemented through the page buffer circuit in the peripheral circuit. FIGS. 19 and 20 show the information processing method of the latch circuit when other grouping methods are employed.

FIG. 19 shows another schematic diagram of each program state of QLC memory cells indicated by group identification information and information of a state to be programmed. As shown in FIG. 19, 15 program states are divided into 2 groups according to the number of program states being 8-7, wherein VPV1′ 19002 (i.e. vpv_p1′) and VPV2′ 19004 (i.e. vpv_p9′) represent the verify voltages for the 1st and 2nd groups, and may correspond to 2 pieces of group identification information (0 and 1) respectively, i.e. the group identification information comprises 1 bit, and may be stored by 1 latch, for example, D1 1808 in FIG. 18.

In FIG. 19, in the 1st group passing the verification that uses VPV1′ 19002, ST1 19021 indicates the memory cells of which target program state is P1, ST2 19022 indicates the memory cells of which target program state is P2, ST3 19023 indicates the memory cells of which target program state is P3, ST4 19024 indicates the memory cells of which target program state is P4, ST5 19025 indicates the memory cells of which target program state is P5, ST6 19026 indicates the memory cells of which target program state is P6, ST7 19027 indicates the memory cells of which target program state is P7, and ST8 19028 indicates the memory cells of which target program state is P8. In the 2nd group passing the verification that uses VPV2′ 19004, ST1 19041 indicates the memory cells of which target program state is P9, ST2 19042 indicates the memory cells of which target program state is P10, ST3 19043 indicates the memory cells of which target program state is P11, ST4 19044 indicates the memory cells of which target program state is P12, ST5 19045 indicates the memory cells of which target program state is P13, ST6 19046 indicates the memory cells of which target program state is P14, and ST7 19047 indicates the memory cells of which target program state is P15. The number of states to be programmed corresponding to the memory cells in 2 groups in FIG. 19 is up to 8, and thus comprises 3 bits (for example, may be 000, 001, 010, 011, 100, 101, 110, or 111), and may be stored by 3 latches, for example, D2 18010, D3 18012, and DC 18014 in FIG. 18.

In some examples, the latches in the first data latch circuit configured to latch the group identification information and the second data latch circuit configured to latch the to-be-programmed state identification information may also be reused. FIG. 20 shows yet another schematic diagram of each program state of a QLC memory cell indicated by group identification information and information of a state to be programmed. As shown in FIG. 20, 15 program states are divided into 5 groups according to the number of program states being 4-4-4-2-1, wherein VPV1″ 20002 (i.e. Vpv_p1′), VPV2″ 20004 (i.e. vpv_p5′), VPV3″ 20006 (i.e. vpv_p9′), VPV4″ 20008 (i.e. vpv_p13′), and VPV5″ 20010 (i.e. vpv_p15′) represent the verify voltages for the 1st, 2nd, 3rd, 4th, and 5th groups, which may correspond to 5 pieces of group identification information (for example, which may be 000, 001, 010, 011, or 100, or may also be 111, 110, 101, 100, or 011, etc., i.e. a combination of any 5 of 8 bit information), i.e. the group identification information comprises 3 bits, and may be stored by 3 latches, for example, D1 1808, D2 18010, and D3 18012 in FIG. 18.

In FIG. 20, in the 1st group passing the verification that uses VPV1″ 20002, ST1 20022 indicates the memory cells of which target program state is P1, ST2 20024 indicates the memory cells of which target program state is P2, ST3 20026 indicates the memory cells of which target program state is P3, and ST4 20028 indicates the memory cells of which target program state is P4. In the 2nd group passing the verification that uses VPV2″ 20004, ST1 20042 indicates the memory cells of which target program state is P5, ST2 20044 indicates the memory cells of which target program state is P6, ST3 20046 indicates the memory cells of which target program state is P7, and ST4 20048 indicates the memory cells of which target program state is P8. The 3rd group passing the verification that uses VPV3″ 20006 is arranged sequentially, indicating the memory cells of which target program states are P9-P12. In the 4th group passing the verification that uses VPV4″ 20008, ST1 20082 indicates the memory cells of which target program state is P13, and ST2 20084 indicates the memory cells of which target program state is P14. In the 5th group passing the verification that uses VPV5″ 20010, ST1 20102 indicates the memory cells of which target program state is P15. The number of states to be programmed corresponding to the memory cells in the 5 groups in FIG. 20 is up to 4, such that the to-be-programmed state identification information comprises 2 bits, and may be stored by 2 latches, for example, D3 18012 and DC 18014 in FIG. 20, i.e. reusing D3 18012 with a latch group latching the group identification information. Suitable latches may be selected for reusing in the practical application.

The method of updating the to-be-programmed state identification information in the process of applying several program pulse voltages by using the grouping methods in FIGS. 18 and 19 is similar to that shown in FIG. 17, and details are not described herein again.

According to the example of the grouping methods provided by the present disclosure, when the operation method of the memory provided by the examples of the present disclosure is actually applied, the grouping methods may be flexibly adjusted according to requirements, such that the overall performance of the memory may be optimized while the total time for programming is shortened.

The examples of the present disclosure all use the QLC memory cell as an example for description, but are not limited thereto. The method of applying the operation method of the memory provided by the examples of the present disclosure to a multi-level memory cell such as an MLC memory cell, a TLC memory cell, etc. is similar to that of applying the operation method of the memory to the QLC memory cell, and details are not described herein again.

Examples of the present disclosure are illustrated and described above. It is to be understood that, the present disclosure is not limited to the detailed structures, setting methods, or implementation methods described herein; rather, the present disclosure is intended to cover a variety of modifications and equivalent settings encompassed within the spirit and scope of the appended claims.

What is claimed is:

1. A method for operating a memory, comprising: at a first program stage,
performing a program operation on memory cells of a target group for a first number of times, wherein the memory cells of the target group comprise a first memory cell and a second memory cell, a target program state of the first memory cell is a first program state, and a target program state of the second memory cell is a second program state;
performing a verify operation on the memory cells of the target group using a verify voltage for the target group; and
after the second memory cell passes the verification that uses the verify voltage for the target group, performing the program operation on the second memory cell for a second number of times, and inhibiting the second memory cell from being verified.

2. The method of claim 1, wherein a threshold voltage of a memory cell in the first program state is less than a threshold voltage of the memory cell in the second program state, the verify voltage for the target group is for verifying whether the memory cell is in a target intermediate state, wherein the target intermediate state is a program target for the first memory cell at the first program stage.

3. The method of claim 1, wherein a threshold voltage of a memory cell in the first program state is less than a threshold voltage of the memory cell in the second program state, and the second program state differs from the first program state by a third number of program states,
wherein:
the second number is greater than the third number; or
the second number is equal to the third number.

4. The method of claim 1, further comprising:
at the first program stage, after performing the program operation on the second memory cell for the second number of times, inhibiting the second memory cell from being programmed.

5. The method of claim 1, further comprising:
at a second program stage, performing a program operation and a corresponding verify operation on the memory cells of the target group, to program the memory cells of the target group to corresponding target program states.

6. The method of claim 1, further comprising:
at the first program stage, after the first memory cell passes the verification that uses the verify voltage for the target group, inhibiting the first memory cell from being programmed.

7. The method of claim 1, further comprising:
at the first program stage, for the memory cells in the target group that do not pass the verification that uses the verify voltage for the target group, continuing performing the program operation, and after performing the program operation, continuing performing the verify operation using the verify voltage for the target group.

8. The method of claim 1, wherein, during performing the program operation on the second memory cell for the second number of times, a program voltage is applied to a selected word line, and an intermediate voltage or a ground voltage is applied to a bit line coupled with the second memory cell, the memory cells coupled with the selected word line comprising the memory cells of the target group, and the intermediate voltage being greater than the ground voltage.

9. The method of claim 8, wherein, during performing the program operation on the memory cells of the target group for the first number of times, the program voltage is applied to the selected word line, and the intermediate voltage or the ground voltage is applied to the bit line coupled with the second memory cell.

10. The method of claim 1, wherein the after the second memory cell passes the verification that uses the verify voltage for the target group, performing the program operation on the second memory cell for a second number of times and inhibiting the second memory cell from being verified comprises:
after the second memory cell passes the verification that uses the verify voltage for the target group, applying a verify inhibit voltage to a bit line coupled with the second memory cell between at least two adjacent program operations during performing the program operation on the second memory cell for the second number of times.

11. The method of claim 1, wherein memory cells to be programmed in the memory have m target program states,
at the first program stage, the memory cells to be programmed in the memory are divided into n groups according to the target program states of the memory cells, wherein n is an integer greater than or equal to 1, and m is an integer greater than n, and
the target group belongs to one of the n groups, the target program states of the memory cells of different groups among the n groups are different, and the memory cells of the same group have the same verify voltage.

12. The method of claim 11, wherein the target group is the 1st group, the verify voltages for the 1st group to the nth group increase sequentially, and the first number is greater than 1, and
the method further comprises: at the first program stage,
performing the verify operation on the memory cells of the 1st group using the verify voltage for the 1st group, between at least two adjacent program operations during performing the program operation on the memory cells of the target group for the first number of times.

13. The method of claim 11, wherein the target group is the kth group, k is an integer greater than or equal to 1 and less than n, and the verify voltages for the 1st group to the nth group increase sequentially, and the method further comprises:
at the first program stage, after performing the verify operation on the memory cells of the target group using the verify voltage for the target group, performing the verify operation on at least part of the memory cells of the (k+1)th group using the verify voltage for the (k+1)th group.

14. The method of claim 11, wherein the target group is the kth group, k is an integer greater than 1 and less than or equal to n, the verify voltages for the 1st group to the nth group increase sequentially, and the first number is greater than 1, and the method further comprises:
at the first program stage, before performing the verify operation on the memory cells of the target group using the verify voltage for the target group, performing the verify operation on the memory cells of the kth group using the verify voltage for the jth group, between at least two adjacent program operations during performing the program operation on the memory cells of the kth group for the first number of times, wherein j is greater than or equal to 1 and less than k.

15. The method of claim 11, wherein m is any integer from 7 to 15, and n is any integer from 2 to 5.

16. The method of claim 1, wherein the memory cells are quadruple level cells QLCs, and the method further comprises:
dividing the memory cells to be programmed, which have 15 target program states, in the memory into 4 groups in order from the minimum to the maximum threshold voltages corresponding to the target program states, wherein the memory cells in the 1st to 3rd group have 4 target program states respectively, the memory cells in the 4th group have 3 target program states, and wherein the target group is any one of the 1st to 4th group.

17. The method of claim 1, wherein the memory cells in the target group have i target program states, and i is an integer greater than 1,
the first program state is a target program state corresponding to the minimum threshold voltage among the i target program states, and the second program state is any one of the i target program states other than the target program state corresponding to the minimum threshold voltage.

18. A memory, comprising:
a memory cell array comprising memory cells of a target group;
a plurality of word lines coupled to rows of the memory cell array respectively;
a plurality of bit lines coupled to memory strings of the memory cell array respectively; and
a peripheral circuit coupled to the memory cell array through the word lines and the bit lines, and configured to: at a first program stage,
perform a program operation on the memory cells of the target group for a first number of times, wherein the memory cells of the target group comprise a first memory cell and a second memory cell, wherein a target program state of the first memory cell is a first program state, and a target program state of the second memory cell is a second program state;
perform a verify operation on the memory cells of the target group using a verify voltage for the target group; and
after the second memory cell passes a verification that uses the verify voltage for the target group, perform the program operation on the second memory cell for a second number of times, and inhibit the second memory cell from being verified.

19. The memory of claim 18, wherein the peripheral circuit comprises:
a plurality of page buffer circuits coupled to the plurality of bit lines respectively, wherein each page buffer circuit comprises:
a data latch circuit comprising:
a first data latch circuit configured to latch group identification information of the target group to which a memory cell belongs; and
a second data latch circuit configured to latch to-be-programmed state identification information of the memory cell in the target group to which it belongs, wherein the group identification information and the to-be-programmed state identification information indicate the target program state of the memory cell; and
a state latch circuit configured to latch first result information of performing the verify operation on the memory cells of the target group using the verify voltage for the target group, and
the peripheral circuit is further configured to:
if the memory cell is determined as the second memory cell according to the group identification information and the to-be-programmed state identification information, and it is determined, according to a result of performing the verify operation, that the second memory cell passes the verification that uses the verify voltage for the target group, perform the program operation on the second memory cell for the second number of times.

20. A memory system, comprising:
a controller; and
a memory coupled with the controller and comprising:
a memory cell array comprising memory cells of a target group;
a plurality of word lines coupled to rows of the memory cell array respectively;
a plurality of bit lines coupled to memory strings of the memory cell array respectively; and
a peripheral circuit coupled to the memory cell array through the word lines and the bit lines, and configured to: at a first program stage,
perform a program operation on the memory cells of the target group for a first number of times, wherein the memory cells of the target group comprise a first memory cell and a second memory cell, wherein a target program state of the first memory cell is a first program state, and a target program state of the second memory cell is a second program state;
perform a verify operation on the memory cells of the target group using a verify voltage for the target group; and
after the second memory cell passes the verification that uses the verify voltage for the target group, perform the program operation on the second memory cell for a second number of times, and inhibit the second memory cell from being verified, and
the memory configured to perform an operation method of the memory, comprising: at the first program stage,
performing the program operation on the memory cells of the target group for the first number of times, wherein the memory cells of the target group comprise the first memory cell and the second memory cell, the target program state of the first memory cell is the first program state, and the target program state of the second memory cell is the second program state;
performing the verify operation on the memory cells of the target group using the verify voltage for the target group; and
after the second memory cell passes the verification that uses the verify voltage for the target group, performing the program operation on the second memory cell for the second number of times, and inhibiting the second memory cell from being verified.
